(19) United States
(12) Patent Application Publication
(10) Pub. No.: US 2026/0096112 A1
(43) Pub. Date: Apr. 2, 2026

(54) SEMICONDUCTOR DEVICE

(71) Applicant: Samsung Electronics Co., Ltd., Suwon-si (KR)

(72) Inventors: Yeji Shin, Suwon-si (KR); Sang-Won Shim, Suwon-si (KR); Jeil Ryu, Suwon-si (KR); Kunyong Yoon, Suwon-si (KR)

(21) Appl. No.: 19/282,826

(22) Filed: Jul. 28, 2025

(30) Foreign Application Priority Data
Sep. 27, 2024 (KR) 10-2024-0132141

(51) Int. Cl. H10D 1/68; H10D 1/00

(52) U.S. Cl. CPC H10D 1/714; H10D 1/042

(57) ABSTRACT

A semiconductor device includes first lower electrode lines and second lower electrode lines provided on a substrate and disposed alternately in a direction that is parallel to an upper surface of the substrate; a first interlayer dielectric; first upper electrode lines and second upper electrode lines provided on the first interlayer dielectric and disposed alternately in the direction, at least one of the first upper electrode lines overlapping in the vertical direction with one of the first lower electrode lines, and at least another of the first upper electrode lines overlapping in the vertical direction with one of the second lower electrode lines; and a via line provided between the at least one first upper electrode line and the first lower electrode line that are in the vertical direction overlapping each other, the via line extending through the first interlayer dielectric.

### CROSS-REFERENCE TO RELATED APPLICATION(S)

This U.S. non-provisional application claims priority under 35 USC § 119 to Korean Patent Application No. 10-2024-0132141, filed on Sep. 27, 2024, in the Korean Intellectual Property Office, the disclosure of which is herein incorporated by reference in its entirety.

### BACKGROUND

A semiconductor device may include various discrete components. For example, discrete components may include transistors, resistors, capacitors, and/or inductors. These discrete components may be electrically connected to each other in an appropriate manner to implement various circuits within the semiconductor device. Some semiconductor devices may require high-capacity capacitors. As semiconductor devices become more highly integrated, areas occupied by the semiconductor devices are decreasing. Therefore, research is ongoing into various methods of implementing higher-capacity capacitors within a limited area.

### SUMMARY

Example implementations provide a semiconductor device including a capacitor with increased capacity.

According to an example implementation, a semiconductor device includes first lower electrode lines and second lower electrode lines provided on a substrate and disposed alternately in one direction, parallel to an upper surface of the substrate, a first interlayer dielectric covering the first lower electrode lines and the second lower electrode lines, first upper electrode lines and second upper electrode lines provided on the first interlayer dielectric and disposed alternately in the one direction, at least one of the first upper electrode lines overlapping perpendicularly with one of the first lower electrode lines, and at least another of the first upper electrode lines overlapping perpendicularly with one of the second lower electrode lines, and a via line provided between the first upper electrode line and the first lower electrode line, perpendicularly overlapping each other, through the first interlayer dielectric. The first upper electrode lines and the first lower electrode lines may be electrically connected to each other, and the second upper electrode lines and the second lower electrode lines may be electrically connected to each other.

According to an example implementation, a semiconductor device includes first lower electrode lines and second lower electrode lines provided on a substrate and disposed alternately in one direction, parallel to an upper surface of the substrate, the first lower electrode lines and the second lower electrode lines being disposed at a first pitch in the one direction, a first interlayer dielectric covering the first lower electrode lines and the second lower electrode lines, first upper electrode lines and second upper electrode lines provided on the first interlayer dielectric and disposed alternately in the one direction, the first upper electrode lines and the second upper electrode lines being disposed at a second pitch, larger than the first pitch, in the one direction, and at least one of the first upper electrode lines overlapping perpendicularly with one of the first lower electrode lines, and at least one via line provided between the first upper electrode lines and the first lower electrode lines, perpendicularly overlapping each other, through the first interlayer dielectric. The first upper electrode lines and the first lower electrode lines may be electrically connected to each other, and the second upper electrode lines and the second lower electrode lines may be electrically connected to each other.

### BRIEF DESCRIPTION OF DRAWINGS

FIG. 1 is a plan view of a semiconductor device according to an example implementation.

FIG. 2 is a perspective view of a semiconductor device according to an example implementation.

FIG. 3 is an exploded perspective view of the semiconductor device illustrated in FIG. 2.

FIG. 4 is a cross-sectional view taken along line I-I′ of FIG. 2.

FIGS. 5 to 8 are cross-sectional views, corresponding to line I-I′ of FIG. 2, illustrating a method of manufacturing a semiconductor device according to an example implementation.

FIG. 9 is a cross-sectional view of a semiconductor device according to an example implementation.

FIG. 10 is a cross-sectional view of a semiconductor device according to an example implementation.

FIGS. 11 to 13 are cross-sectional views illustrating a method of manufacturing a semiconductor device according to an example implementation.

FIG. 14 is a cross-sectional view of a semiconductor device according to an example implementation.

FIG. 15 is a cross-sectional view of a semiconductor device according to an example implementation.

FIG. 16 is a cross-sectional view of a semiconductor device according to an example implementation.

FIG. 17 is a cross-sectional view of a semiconductor device according to an example implementation.

FIG. 18 is a cross-sectional view of a semiconductor device according to an example implementation.

FIG. 19 is a perspective view of a semiconductor device according to an example implementation.

FIG. 20 is an exploded perspective view of the semiconductor device illustrated in FIG. 19.

FIG. 21 is a cross-sectional view taken along line II-II′ of FIG. 19.

FIGS. 22 to 25 are cross-sectional views, corresponding to line II-II′ of FIG. 19, illustrating a method of manufacturing a semiconductor device according to an example implementation.

FIG. 26 is a cross-sectional view of a semiconductor device according to an example implementation.

FIG. 27 is a cross-sectional view of a semiconductor device according to an example implementation.

FIGS. 28 to 36 are cross-sectional views illustrating a method of manufacturing a semiconductor device according to an example implementation.

FIG. 37 is a cross-sectional view of a semiconductor device according to an example implementation.

### DETAILED DESCRIPTION

Hereinafter, example implementations will be described with reference to the accompanying drawings.

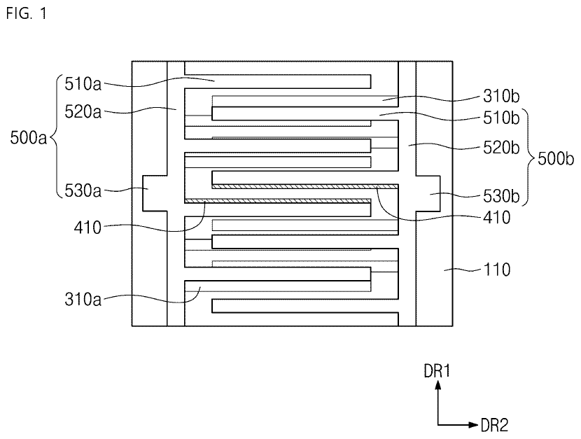

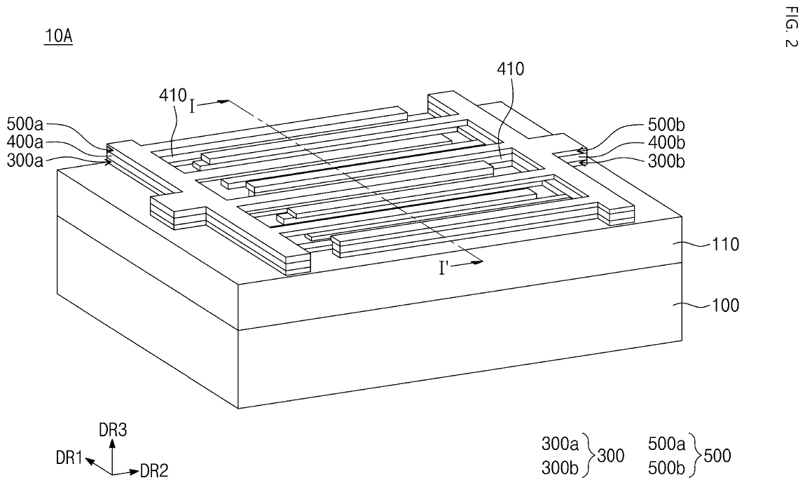

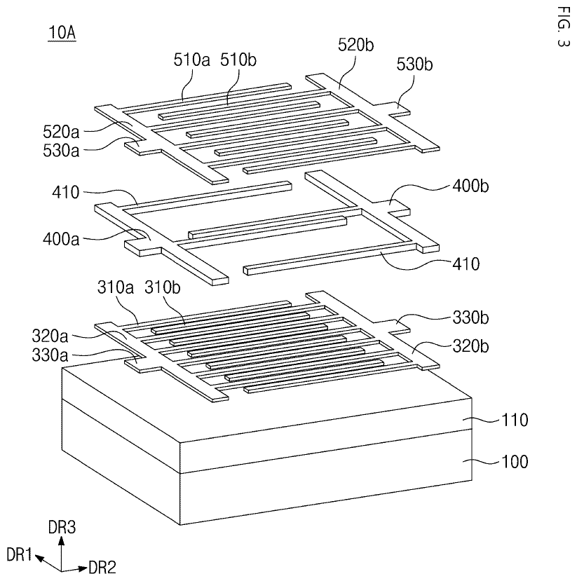

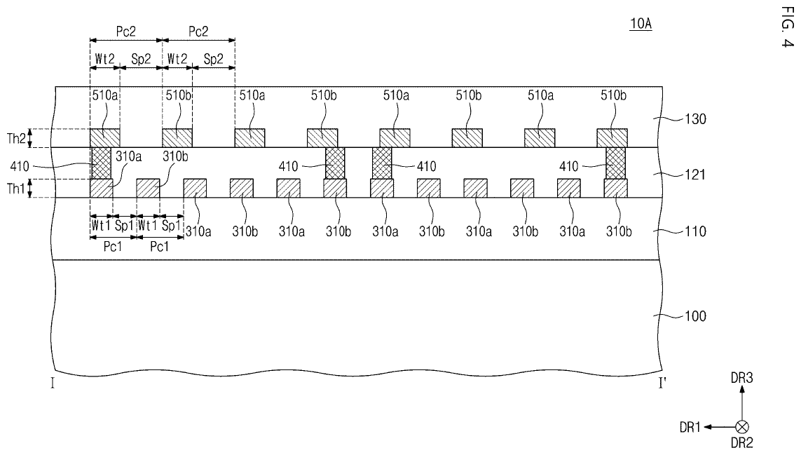

FIG. 1 is a plan view of a semiconductor device 10A according to an example implementation. FIG. 2 is a perspective view of the semiconductor device 10A according to an example implementation. FIG. 3 is an exploded perspective view illustrating the semiconductor device 10A of FIG. 2. FIG. 4 is a cross-sectional view taken along line I-I′ of FIG. 2.

Referring to FIGS. 1 to 4, the semiconductor device 10A may include an upper electrode pattern 500 and a lower electrode pattern 300, both provided on a substrate 100, and at least one via line 410 provided between the upper electrode pattern 500 and the lower electrode pattern 300.

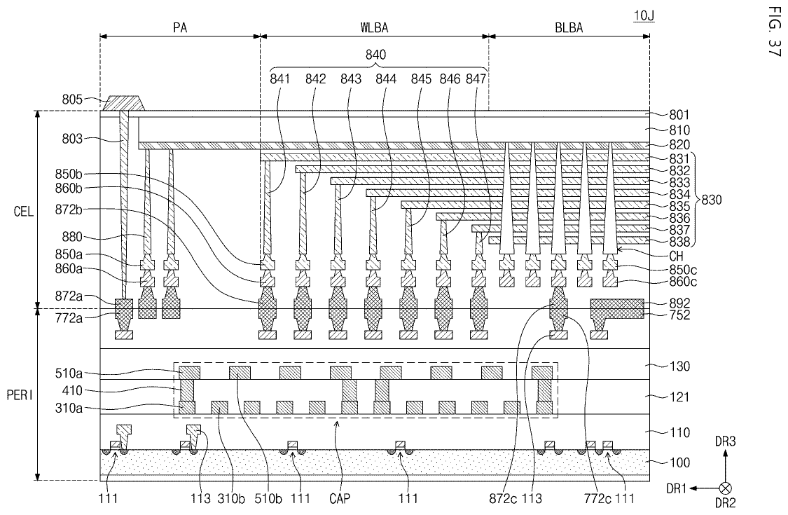

The substrate 100 may be a semiconductor substrate including silicon, germanium, silicon-germanium, or a compound semiconductor substrate. For example, the substrate 100 may be a silicon substrate. The substrate 100 may correspond to a first substrate 100 of FIG. 37.

A lower interlayer dielectric 110 may be provided on the substrate 100. The upper electrode pattern 500 and the lower electrode pattern 300 may be provided over a lower interlayer dielectric 110. The lower interlayer dielectric 110 may cause the upper electrode pattern 500 and the lower electrode pattern 300 to be spaced apart from the substrate 100.

The lower electrode pattern 300 may be provided on the lower interlayer dielectric 110. The lower electrode pattern 300 may include a first lower electrode pattern 300a and a second lower electrode pattern 300b that are spaced apart from each other. The first lower electrode pattern 300a and the second lower electrode pattern 300b may constitute different electrodes.

The lower electrode pattern 300 may include first lower electrode lines 310a and second lower electrode lines 310b that are alternately disposed. For example, the first lower electrode pattern 300a may include the first lower electrode lines 310a. The second lower electrode pattern 300b may include the second lower electrode lines 310b. The first lower electrode lines 310a and the second lower electrode lines 310b may be alternately disposed in one direction, parallel to an upper surface of the substrate 100.

The first lower electrode lines 310a and the second lower electrode lines 310b may be elongated. For example, the first lower electrode lines 310a and the second lower electrode lines 310b may be elongated in a direction, perpendicular to a direction in which the first and second lower electrode lines 310a and 310b are alternately disposed. For example, the first lower electrode lines 310a and the second lower electrode lines 310b may be alternately formed in a first direction DR1 and may be elongated in a second direction DR2, perpendicular to the first direction DR1.

The first lower electrode lines 310a and the second lower electrode lines 310b may be alternately formed. The first lower electrode lines 310a and the second lower electrode lines 310b may be disposed to be spaced apart from each other. For example, the first lower electrode lines 310a and the second lower electrode lines 310b may be spaced apart from each other in the first direction DR1 and/or the second direction DR2. As a result, the first lower electrode lines 310a and the second lower electrode lines 310b may constitute different electrodes.

The first lower electrode lines 310a and the second lower electrode lines 310b may be disposed at a constant pitch. For example, the first lower electrode lines 310a and the second lower electrode lines 310b may be disposed at a first pitch Pc1 in the first direction DR1.

The pitch may be equal to the sum of a width of an electrode line and a spacing between electrode lines. The first pitch Pc1 may be equal to the sum of a first width Wt1 of a first lower electrode line 310a and a first spacing Sp1 between the first lower electrode line 310a and the second lower electrode line 310b. Alternatively, the first pitch Pc1 may be equal to the sum of a first width Wt1 of the second lower electrode line 310b and a first spacing Sp1 between the first lower electrode line 310a and the second lower electrode line 310b.

A width of the first lower electrode line 310a may be a width of one of the first lower electrode lines 310a. Widths of the first lower electrode lines 310a may be substantially the same. The width of the second lower electrode line 310b may be a width of one of the second lower electrode lines 310b. Widths of the second lower electrode lines 310b may be substantially the same. The width of the first lower electrode line 310a and the width of the second lower electrode line 310b may be substantially the same.

The width of the first lower electrode line 310a or the width of the second lower electrode line 310b may be measured in the first direction DR1. A spacing between the first lower electrode line 310a and the second lower electrode line 310b may be measured in the first direction DR1.

The first lower electrode line 310a and the second lower electrode line 310b may have first thicknesses Th1. The first thickness Th1 may be measured in a third direction DR3.

The first lower electrode pattern 300a may include a first lower strap line 320a connecting the first lower electrode lines 310a. The second lower electrode pattern 300b may include a second lower strap line 320b connecting the second lower electrode lines 310b. The first lower strap line 320a may be connected to one end of each of the first lower electrode lines 310a in a length direction. The second lower strap line 320b may be connected to one end of each of the second lower electrode lines 310b in a length direction. One end of each of the first lower electrode lines 310a in the length direction and one end of each of the second lower electrode lines 310b in the length direction may oppose each other.

The first lower strap line 320a and the second lower strap line 320b may be spaced apart from each other. The first lower strap line 320a and the second lower strap line 320b may be substantially parallel to each other. For example, the first lower strap line 320a and the second lower strap line 320b may be elongated in the first direction DR1 and may be spaced apart from each other in the second direction DR2, perpendicular to the first direction DR1. The first lower electrode lines 310a and the second lower electrode lines 310b may be provided between the first lower strap line 320a and the second lower strap line 320b.

The first lower electrode pattern 300a may include a first lower pad 330a connected to the first lower strap line 320a. Thus, the first lower strap line 320a connected to the first lower pad 330a and the first lower electrode lines 310a connected to the first lower strap line 320a may constitute a first electrode. For example, the first lower pad 330a, the first lower strap line 320a, and the first lower electrode lines 310a may be electrically connected, and the first lower electrode pattern 300a may constitute a first electrode. In an example implementation, the first lower pad 330a, the first lower strap line 320a, and the first lower electrode lines 310a may be integrally provided.

The second lower electrode pattern 300b may include a second lower pad 330b connected to the second lower strap line 320b. The second lower strap line 320b connected to the second lower pad 330b and the second lower electrode lines 310b connected to the second lower strap line 320b may constitute a second electrode. For example, the second lower pad 330b, the second lower strap line 320b, and the second lower electrode lines 310b may be electrically connected, and the second lower electrode pattern 300b may constitute the second electrode. In an example implementation, the second lower pad 330b, the second strap line, and the second lower electrode lines 310b may be integrally provided.

A first interlayer dielectric 121 may cover the first lower electrode lines 310a and the second lower electrode lines 310b. The first interlayer dielectric 121 may be provided on the lower interlayer dielectric 110. For example, the first interlayer dielectric 121 may cover the first lower electrode pattern 300a and the second lower electrode pattern 300b provided on the lower interlayer dielectric 110. The first interlayer dielectric 121 may fill a space between the first lower electrode lines 310a and the second lower electrode lines 310b. Thus, the first interlayer dielectric 121 may be disposed between the first lower electrode lines 310a and the second lower electrode lines 310b. Accordingly, the first electrode, the second electrode, and the first interlayer dielectric 121 provided therebetween may constitute a capacitor. The first interlayer dielectric 121 between the first and second electrodes may function as a dielectric of the capacitor.

An upper electrode pattern 500 may be provided on the first interlayer dielectric 121. The upper electrode pattern 500 may be provided over the lower electrode pattern 300. The upper electrode pattern 500 may vertically overlap the lower electrode pattern 300. Hereinafter, the vertical direction may be the third direction DR3.

The upper electrode pattern 500 may include a first upper electrode pattern 500a and a second upper electrode pattern 500b, which are spaced apart from each other. The first upper electrode pattern 500a and the second upper electrode pattern 500b may constitute different electrodes.

The upper electrode pattern 500 may include first upper electrode lines 510a and second upper electrode lines 510b that are alternately disposed. For example, the first upper electrode pattern 500a may include the first upper electrode lines 510a. The second upper electrode pattern 500b may include the second upper electrode lines 510b. The first upper electrode lines 510a and the second upper electrode lines 510b may be alternately disposed in a direction, parallel to the upper surface of the substrate 100.

The first upper electrode lines 510a and the second upper electrode lines 510b may be elongated. For example, the first upper electrode lines 510a and the second upper electrode lines 510b may be elongated in a direction, perpendicular to a direction in which the first upper electrode lines 510a and the second upper electrode lines 510b are alternately disposed. For example, the first upper electrode lines 510a and the second upper electrode lines 510b may be alternately formed in the first direction DR1 and may be elongated in the second direction DR2, perpendicular to the first direction DR1.

The first upper electrode lines 510a and the second upper electrode lines 510b may be alternately formed. The first upper electrode lines 510a and the second upper electrode lines 510b may be disposed to be spaced apart from each other. For example, the first upper electrode lines 510a and the second upper electrode lines 510b may be spaced apart from each other in the first direction DR1 and/or the second direction DR2. As a result, the first upper electrode lines 510a and the second upper electrode lines 510b may constitute different electrodes.

The first upper electrode lines 510a and the second upper electrode lines 510b may be disposed at a constant pitch. For example, the first upper electrode lines 510a and the second upper electrode lines 510b may be disposed at a second pitch Pc2 in the first direction DR1.

The second pitch Pc2 may be equal to the sum of a second width Wt2 of the first upper electrode line 510a and a second spacing Sp2 between the first upper electrode line 510a and the second upper electrode line 510b. Alternatively, the second pitch Pc2 may be equal to the sum of a width of the second upper electrode line 510b and a spacing between the first upper electrode line 510a and the second upper electrode line 510b.

The second pitch Pc2 may be different from the first pitch Pc1. In an example implementation, the second pitch Pc2 may be larger than the first pitch Pc1. In an example implementation, the second width Wt2 may be larger than the first width Wt1. In an example implementation, the second spacing Sp2 may be larger than the first spacing Sp1.

A material of the first upper electrode lines 510a and a material of the second upper electrode lines 510b may be substantially the same. A material of the first lower electrode lines 310a and a material of the second lower electrode lines 310b may be substantially the same. The material of the first and second upper electrode lines 510a and 510b and the material of the first and second lower electrode lines 310a and 310b may include a conductive material. For example, the material of the first and second upper and lower electrode lines 310a, 310b, 510a, and 510b may include a conductive metal material such as copper, tungsten, aluminum, molybdenum, or cobalt.

In an example implementation, the material of the first and second lower electrode lines 310a and 310b and the material of the first and second upper electrode lines 510a and 510b may be different from each other. For example, the first and second lower electrode lines 310a and 310b may include tungsten, and the first and second upper electrode lines 510a and 510b may include copper.

The width of the first upper electrode line 510a may a width of one of the first upper electrode lines 510a. Widths of the first upper electrode lines 510a may be substantially the same. A width of the second upper electrode line 510b may be a width of one of the second upper electrode lines 510b. Widths of the second upper electrode lines 510b may be substantially the same. The width of the first upper electrode line 510a and the width of the second upper electrode line 510b may be substantially the same.

The widths of the first upper electrode lines 510a or the widths of the second upper electrode lines 510b may be measured in the first direction DR1. The spacing between the first upper electrode line 510a and the second upper electrode line 510b may be measured in the first direction DR1.

The first upper electrode lines 510a and the second upper electrode lines 510b may have second thicknesses Th2. The second thickness Th2 may be measured in the third direction DR3.

The first upper electrode pattern 500a may include a first upper strap line 520a connecting the first upper electrode lines 510a. The second upper electrode pattern 500b may include a second upper strap line 520b connecting the second upper electrode lines 510b. The first upper strap line 520a may be connected to one end of the first upper electrode lines 510a in a length direction. The second upper strap line 520b may be connected to one end of the second upper electrode lines 510b in a length direction. The one end of the first upper electrode lines 510a in the length direction and the one end of the second upper electrode lines 510b in the length direction may oppose each other.

The first upper strap line 520a and the second upper strap line 520b may be spaced apart from each other. The first upper strap line 520a and the second upper strap line 520b may be substantially parallel to each other. For example, the first upper strap line 520a and the second upper strap line 520b may be elongated in the first direction DR1 and may be spaced apart from each other in the second direction DR2, perpendicular to the first direction DR1. The first upper electrode lines 510a and the second upper electrode lines 510b may be provided between the first upper strap line 520a and the second upper strap line 520b.

The first upper electrode pattern 500a may include a first upper pad 530a connected to the first upper strap line 520a. Thus, the first upper strap line 520a connected to the first upper pad 530a and the first upper electrode lines 510a connected to the first upper strap0 line 520a may constitute a first electrode. For example, the first upper pad 530a, the first upper strap line 520a, and the first upper electrode lines 510a may be electrically connected, and the first upper electrode pattern 500a may constitute a first electrode. In an example implementation, the first upper pad 530a, the first upper strap line 520a, and the first upper electrode lines 510a may be integrally provided.

The second upper electrode pattern 500b may include a second upper pad 530b connected to the second upper strap line 520b. Also, the second upper strap line 520b connected to the second upper pad 530b and the second upper electrode lines 510b connected thereto may constitute a second electrode. That is, the second upper pad 530b, the second upper strap line 520b, and the second upper electrode lines 510b are electrically connected, and the second upper electrode pattern 500b may constitute the second electrode. In one implementation, the second upper pad 530b, the second upper strap line 520b, and the second upper electrode lines 510b may be integrally provided.

An upper interlayer dielectric 130 may cover the first upper electrode lines 510a and the second upper electrode lines 510b. The upper interlayer dielectric 130 may be provided on the first interlayer dielectric 121. For example, the upper interlayer dielectric 130 may cover the first upper electrode pattern 500a and the second upper electrode pattern 500b provided on the first interlayer dielectric 121. The upper interlayer dielectric 130 may fill a space between the first upper electrode lines 510a and the second upper electrode lines 510b. Thus, the upper interlayer dielectric 130 may be disposed between the first upper electrode lines 510a and the second upper electrode lines 510b.

The upper interlayer dielectric 130 may include at least one of a silicon oxide, a silicon nitride, or a silicon oxynitride.

The first upper electrode lines 510a may be provided over the first lower electrode lines 310a. The first upper electrode lines 510a may vertically overlap the first lower electrode lines 310a. For example, at least one of the first upper electrode lines 510a may vertically overlap one of the first lower electrode lines 310a. In contrast, at least one of the remaining first upper electrode lines 510a may not vertically overlap one of the first lower electrode lines 310a. For example, the first upper electrode lines 510a and the second upper electrode lines 510b are disposed at a first pitch Pc1 and the first lower electrode lines 310a and the second lower electrode lines 310b are disposed at a second pitch Pc2, different from the first pitch Pc1, so that one or a portion of the first upper electrode lines 510a may overlap the first lower electrode lines 310a, while the remaining portion of the first upper electrode lines 510a may not overlap the first lower electrode lines 310a. The remaining portion of the first upper electrode lines 510a may overlap the second lower electrode lines 310b or the first spacing Sp1.

Vertical overlap may involve positioning the entire single first lower electrode line 310a under a single first upper electrode line 510a. In addition, vertical overlap may involve positioning a portion of a single first lower electrode line 310a under a portion of a single first upper electrode line 510a. The remaining portion of the single first lower electrode line 310a may not be positioned under the single first upper electrode line 510a. On end of the single first upper electrode line 510a in a width direction may be positioned over the single first lower electrode line 310a.

Similarly, the second upper electrode lines 510b may be provided over the second lower electrode lines 310b. The second upper electrode lines 510b may vertically overlap the second lower electrode lines 310b. For example, at least one of the second upper electrode lines 510b may vertically overlap one of the second lower electrode lines 310b. In contrast, at least one of the remaining second upper electrode lines 510b may not overlap one of the second lower electrode lines 310b vertically. For example, one or a portion of the second upper electrode lines 510b may overlap the second lower electrode lines 310b, but the remaining portion of the second upper electrode lines 510b may not overlap the second lower electrode lines 310b. The remaining portion of the second upper electrode lines 510b may overlap the first lower electrode lines 310a or the first spacing Sp1.

Similarly to the first lower electrode lines 310a and the first upper electrode lines 510a, the definition of vertical overlap may be applied to the second lower electrode lines 310b and the second upper electrode lines 510b.

A via line 410 may be provided between the first upper electrode line 510a and the first lower electrode line 310a that overlap each other. For example, the via line 410 may be provided between one of the first upper electrode lines 510a and one of the first lower electrode lines 310a that vertically overlap each other. Via lines 410 may be provided between a portion of the first upper electrode lines 510a and a portion of the first lower electrode lines 310a that vertically overlap each other. The via line 410 may penetrate through the first interlayer dielectric 121.

A material of the via line 410 may include a conductive material. For example, the material of the via line 410 may include a conductive metal material such as copper, tungsten, aluminum, molybdenum, or cobalt.

Similarly, a via line 410 may also be provided between the second upper electrode line 510b and the second lower electrode line 310b that overlap each other. For example, the via line 410 may be provided between one of the second upper electrode lines 510b and one of the second lower electrode lines 310b that vertically overlap each other. Alternatively, via lines 410 may be provided between a portion of the second upper electrode lines 510b and a portion of the second lower electrode lines 310b that vertically overlap each other. For example, the via line 410 may be provided between an upper electrode line and a lower electrode line connected to the same electrode.

The first upper electrode pattern 500a and the first lower electrode pattern 300a may be electrically connected to each other. The second upper electrode pattern 500b and the second lower electrode pattern 300b may be electrically connected to each other.

The via line 410 may be in contact with the first upper electrode line 510a. Similarly, the via line 410 may be in contact with the second upper electrode line 510b. Thus, the via line 410 may be electrically connected to the first upper electrode line 510a and the second upper electrode line 510b. Accordingly, the first upper electrode lines 510a, the first lower electrode lines 310a, and the via line 410 therebetween may constitute a first electrode, and the second upper electrode lines 510b, the second lower electrode lines 310b, and the via line 410 therebetween may constitute a second electrode. As a result, the first electrode, the second electrode, and the first interlayer dielectric 121 and the upper interlayer dielectric 130 therebetween may constitute a capacitor. The first interlayer dielectric 121 and the upper interlayer dielectric 130 may function as a dielectric.

Accordingly, capacitance of a capacitor may increase due to at least one via line 410 provided between the lower electrode lines 310a and 310b and the upper electrode lines 510a and 510b.

A first via pattern 400a may be provided between the first upper electrode pattern 500a and the first lower electrode pattern 300a. For example, the first via pattern 400a may be provided between the first upper strap line 520a and the first lower strap line 320a. The first via pattern 400a may extend between the first upper pad 530a and the first lower pad 330a. In an example implementation, the first via pattern 400a may be integrally provided with a portion of the via lines 410.

A second via pattern 400b may be provided between the second upper electrode pattern 500b and the second lower electrode pattern 300b. For example, the second via pattern 400b may be provided between the second upper strap line 520b and the second lower strap line 320b. The second via pattern 400b may extend between the second upper pad 530b and the second lower pad 330b. In an example implementation, the second via pattern 400b may be integrally provided with the remaining portion of the via lines 410.

The via line 410 may be connected to the first via pattern 400a or the second via pattern 400b. A portion of the via lines 410 may be connected to the first via pattern 400a, and the remaining portion of the via lines 410 may be connected to the second via pattern 400b. For example, the via lines 410 provided between the first upper electrode lines 510a and the first lower electrode lines 310a may be connected to the first via pattern 400a. The via lines 410 provided between the second upper electrode lines 510b and the second lower electrode lines 310b may be connected to the second via pattern 400b.

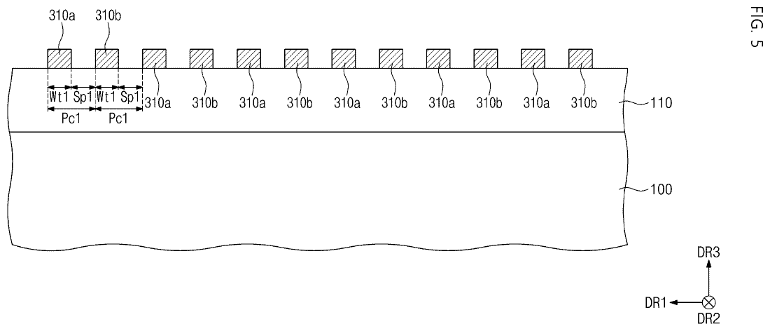

FIGS. 5 to 8 are cross-sectional views, corresponding to line I-I′ of FIG. 2, illustrating a method of manufacturing a semiconductor device 100A according to an example implementation.

Referring to FIG. 5, a lower interlayer dielectric 110 may be formed on a substrate 100. The lower interlayer dielectric 110 may include at least one of a silicon oxide, a silicon nitride, or a silicon oxynitride.

First lower electrode lines 310a and second lower electrode lines 310b may be alternately formed on the lower interlayer dielectric 110. The first lower electrode lines 310a and second lower electrode lines 310b, formed alternately, may be disposed at a first pitch Pc1 in a first direction DR1.

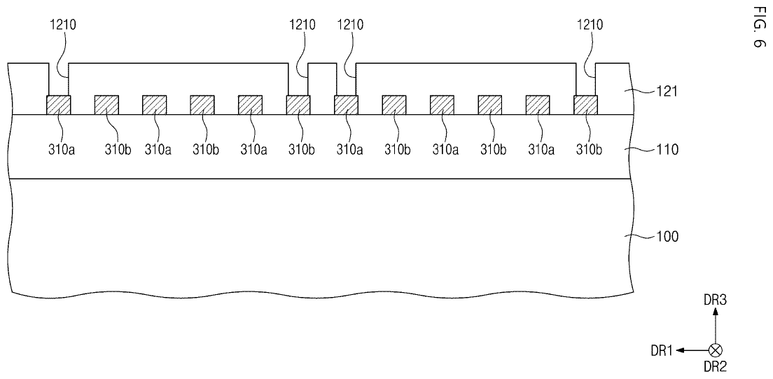

Referring to FIG. 6, a first interlayer dielectric 121 may be formed on the lower interlayer dielectric 110. The first interlayer dielectric 121 may cover the first lower electrode lines 310a and the second lower electrode lines 310b. The first interlayer dielectric 121 may include at least one of a silicon oxide, a silicon nitride, or a silicon oxynitride.

A first groove 1210 may be formed to penetrate through the first interlayer dielectric 121. The first groove 1210 may be formed in the first interlayer dielectric 121. The first groove 1210 may extend in a second direction DR2. The first groove 1210 may be formed to expose an upper surface of one of the first lower electrode lines 310a and/or an upper surface of one of the second lower electrode lines 310b. Alternatively, the first grooves 1210 may be formed to expose upper surfaces of a portion of the first lower electrode lines 310a and/or upper surfaces of a portion of the second lower electrode lines 310b. The remaining portion of the first lower electrode lines 310a and the remaining portion of the second lower electrode lines 310b may be covered with the first interlayer dielectric 121.

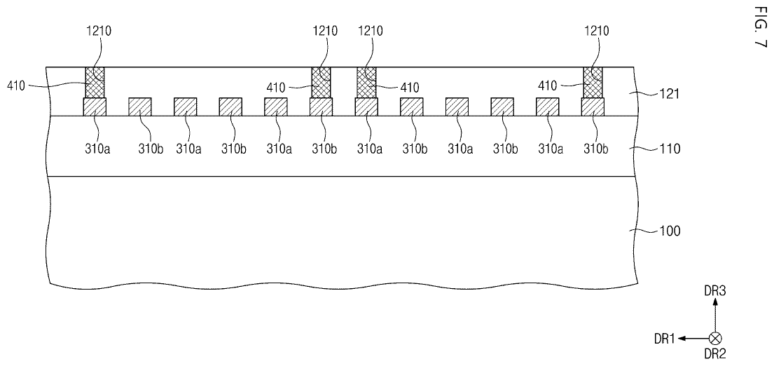

Referring to FIG. 7, a via conductive layer, not illustrated, may be formed on the first interlayer dielectric 121 to fill at least one first groove 1210. The via conductive layer, not illustrated, may cover an upper surface of the first interlayer dielectric 121.

The via conductive layer, not illustrated, may be planarized until the upper surface of the first interlayer dielectric 121 is exposed. The planarization of the via conductive layer, not illustrated, may be performed using an etch-back process or a chemical mechanical polishing (CMP) process. As a result, at least one via line 410 may be formed to fill at least one first groove 1210. An upper surface of at least one via line 410 may be substantially coplanar with the upper surface of the first interlayer dielectric 121.

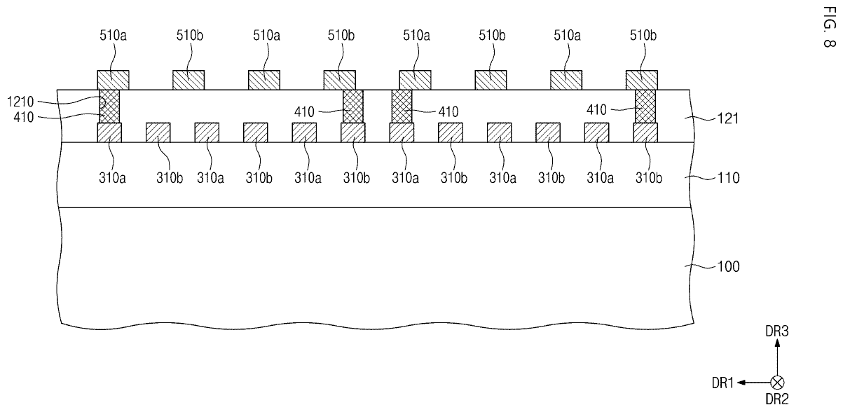

Referring to FIG. 8, first upper electrode lines 510a and second upper electrode lines 510b may be alternately formed on the first interlayer dielectric 121. The formed first upper electrode lines 510a and second upper electrode lines 510b may be disposed at a second pitch Pc2 in a first direction DR1.

One or a portion of the first upper electrode lines 510a may be formed on at least one via line 410. For example, one or a portion of the first upper electrode lines 510a may be in contact with an upper surface of at least one via line 410. The remaining portion of the first upper electrode lines 510a may be formed on the first interlayer dielectric 121.

Similarly, one or a portion of the second upper electrode lines 510b may be formed on at least one via line 410. For example, one or a portion of the second upper electrode lines 510b may be in contact with the upper surface of at least one via line 410. The remaining portion of the second upper electrode lines 510b may be formed on the first interlayer dielectric 121.

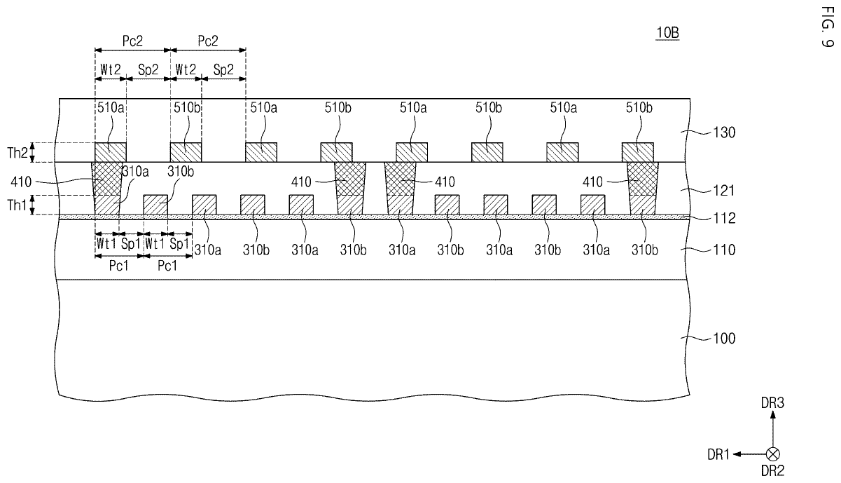

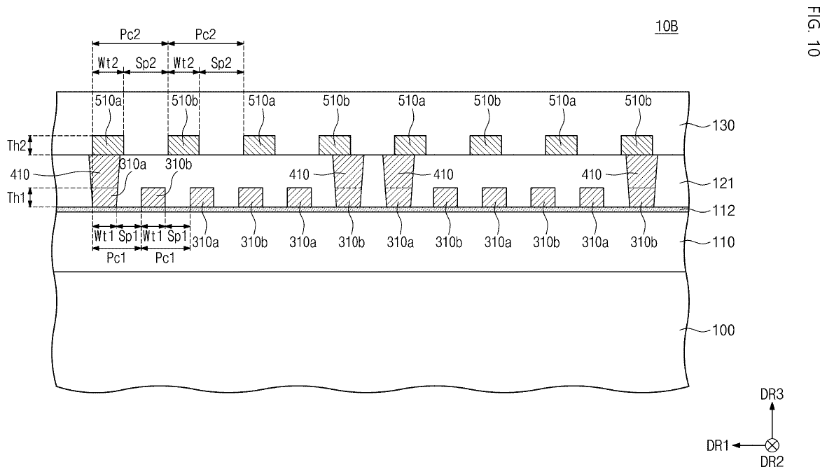

FIG. 9 is a cross-sectional view of a semiconductor device 10B according to an example implementation. FIG. 10 is a cross-sectional view of a semiconductor device 10B according to an example implementation.

Referring to FIG. 9, one or a portion of first lower electrode lines 310a may vertically overlap one or a portion of the first upper electrode lines 510a, and at least one via line 410 may be provided between one or a portion of the first lower electrode lines 310a and one or a portion of the first upper electrode lines 510a that overlap each other. The one or a portion of the first lower electrode lines 310a may be provided to be integrated with at least one via line 410. A material of the first lower electrode lines 310a may be substantially the same as a material of the via line 410.

Similarly, one or a portion of the second lower electrode lines 310b may be provided to be integrated with the via line 410. In an example implementation, referring to FIG. 10, a material of the second lower electrode lines 310b may be the same as a material of the via line 410.

A width of the integrated portion may increase in an upward direction. For example, a width of the one or a portion of the first lower electrode lines 310a may increase in an upward direction. Also, a width of the one or a portion of the second lower electrode lines 310b may increase in an upward direction. A width of the via line 410 may increase in an upward direction. A width of a lower portion of the via line 410 may be substantially equal to a width of an upper end of one of the first lower electrode lines 310a or widths of upper ends of a portion of the first lower electrode lines 310a. Also, the width of the lower portion of the via line 410 may be substantially equal to the width of the upper end of one of the second lower electrode lines 310b or the widths of the upper ends of a portion of the second lower electrode lines 310b.

A side surface of the via line 410 may be substantially coplanar with a side surface of one of the first lower electrode lines 310a or some of the side surfaces thereof. The side surface of the via line 410 may be substantially coplanar with a side surface of one of the second lower electrode lines 310b or side surfaces of a portion of the second lower electrode lines 310b.

In the first and second lower electrode lines 310a and 310b each having a width increased in the upward direction, the first pitch Pc1 may be measured with respect to a lower end of each of the first and second lower electrode lines 310a and 310b. For example, the first width Wt1 constituting the first pitch Pc1 may be equal to a width of the lower end of the first electrode line 310a or the second lower electrode line 310b. Also, the first spacing Sp1 constituting the first pitch Pc1 may be equal to a spacing between the lower end of the first lower electrode line 310a and the lower end of the second lower electrode line 310b.

An etch-stop layer 112 may be provided between the first interlayer dielectric 121 and the lower interlayer dielectric 110. The first lower electrode lines 310a and the second lower electrode lines 310b may be provided on the etch-stop layer 112.

A width of the remaining portion of the first lower electrode lines 310a may remain constant in an upward direction. However, example implementations are not limited thereto, and the widths of the remaining portion of the first lower electrode lines 310a may also increase in the upward direction, similarly to the width of the one or a portion of the first lower electrode lines 310a.

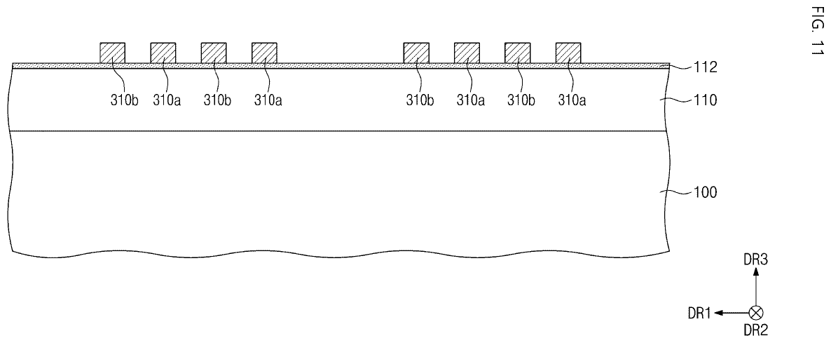

FIGS. 11 to 13 are cross-sectional views illustrating a method of manufacturing a semiconductor device 10B according to an example implementation.

Referring to FIG. 11, a lower interlayer dielectric 110 may be provided on a substrate 100. The lower interlayer dielectric 110 may include at least one of a silicon oxide, a silicon nitride, or a silicon oxynitride.

An etch-stop layer 112 may be provided on the lower interlayer dielectric 110. A material of the etch-stop layer 112 may be different from a material of the lower interlayer dielectric 110. The etch-stop layer 112 may have an etch selectivity with respect to an underlying lower interlayer dielectric 110. For example, the lower interlayer dielectric 110 may be formed of a silicon oxide, and the etch-stop layer 112 may be formed of a silicon nitride and/or a silicon oxynitride.

First lower electrode lines 310a and second lower electrode lines 310b may be formed on the etch-stop layer 112. However, one or a portion of the first lower electrode lines 310a and one or a portion of the second lower electrode lines 310b may not be formed. For example, except for one or a portion of the first lower electrode lines 310a overlapping the first upper electrode lines 510a, the rest may be formed on the etch-stop layer 112. Also, except for one or a portion of the second lower electrode lines 310b overlapping the second upper electrode lines 510b, the rest may be formed on the etch-stop layer 112. The rest of the first lower electrode lines 310a and the rest of the second lower electrode lines 310b may be formed in consideration of locations of one or a portion of the first lower electrode lines 310a and one or a portion of the second lower electrode lines 310b to be formed later.

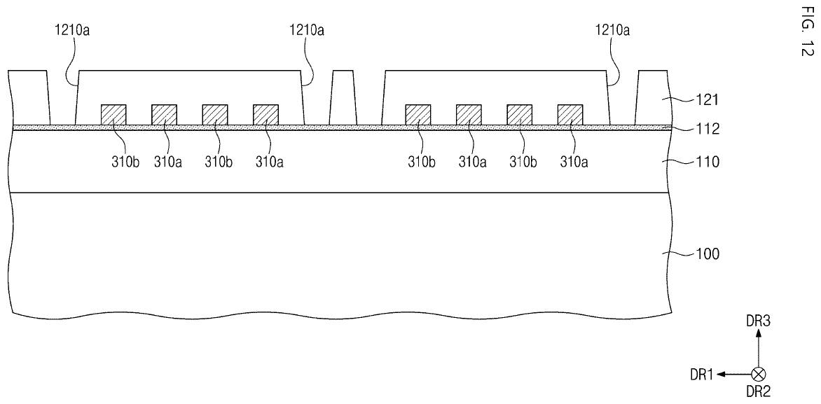

Referring to FIG. 12, a first interlayer dielectric 121 may be formed on the etch-stop layer 112. The first interlayer dielectric 121 may cover the rest of the first lower electrode lines 310a and the rest of the second lower electrode lines 310b.

At least one first groove 1210a may be formed to penetrate through the first interlayer dielectric 121. The first groove 1210a may be formed in the first interlayer dielectric 121. The at least one first groove 1210a may be formed at a location at which one or a portion of the first lower electrode lines 310a and one or a portion of the second lower electrode lines 310b are to be formed. The first groove 1210a may be recessed until an upper surface of the etch-stop layer 112 is exposed. The first groove 1210a may extend in a second direction DR2.

The width of the first groove 1210a may gradually increase in an upward direction. The width of the first groove 1210a may be measured in a first direction DR1.

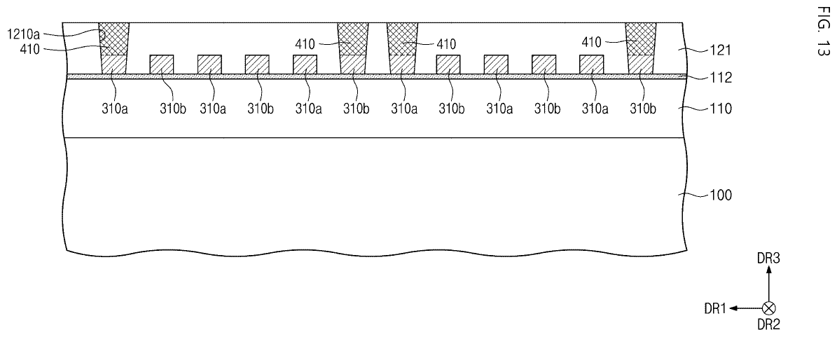

Referring to FIG. 13, one or a portion of the first lower electrode lines 310a may be formed in at least one first groove 1210a. One or a portion of the second lower electrode lines 310b may be formed in at least one first groove 1210a. For example, one or a portion of the first lower electrode lines 310a may fill a lower portion of at least one first groove 1210a. The one or a portion of the second lower electrode lines 310b may fill a lower portion of the at least one first groove 1210a. A via conductive layer, not illustrated, may be formed on the first and/or second lower electrode lines 310a and 310b. The via conductive layer, not illustrated, may also be formed on the first interlayer dielectric 121. In an example implementation, the material of the first and second lower electrode lines 310a and 310b and the material of the via conductive layer, not illustrated, are substantially the same, so that the first and second lower electrode lines 310a and 310b and the via conductive layer may be continuously formed.

The via conductive layer, not illustrated, may be planarized until an upper surface of the first interlayer dielectric 121 is exposed. The planarization of the via conductive layer, not illustrated, may be performed using an etch-back process or a chemical mechanical polishing (CMP) process. As a result, at least one via line 410 may be formed to fill at least one first groove 1210a. An upper surface of at least one via line 410 may be substantially coplanar with the upper surface of the first interlayer dielectric 121.

Referring back to FIG. 8, first upper electrode lines 510a and second upper electrode lines 510b may be formed on the first interlayer dielectric 121. The first upper electrode lines 510a and the second upper electrode lines 510b may be alternately formed in a first direction DR1 and disposed at a second pitch Pc2.

One or a portion of the first upper electrode lines 510a may be formed on the via line 410. For example, the one or a portion of the first upper electrode lines 510a may be in contact with an upper surface of the via line 410. The remaining of the first upper electrode lines 510a may be formed on the first interlayer dielectric 121.

Similarly, one or a portion of the second upper electrode lines 510b may be formed on the via line 410. For example, the one or a portion of the second upper electrode lines 510b may be in contact with the upper surface of the via line 410. The remaining of the second upper electrode lines 510b may be formed on the first interlayer dielectric 121.

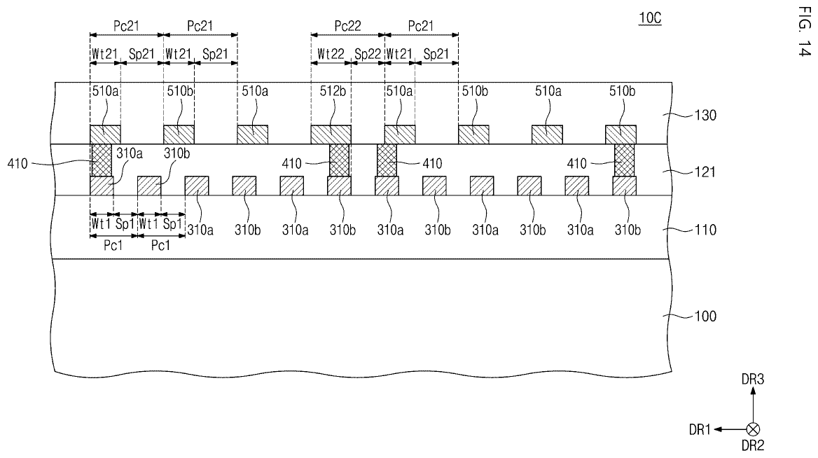

FIG. 14 is a cross-sectional view of a semiconductor device 10C according to an example implementation.

Referring to FIG. 14, in an example implementation, one or a portion of first upper electrode lines 510a may be extended. For example, a width of one, or widths of a portion, of the first upper electrode lines 510a disposed on at least one via line 410 may be selectively extended. For example, widths Wt21 and Wt22 of one or a portion of the first upper electrode lines 510a may be substantially equal to or larger than a width Wt21 of the rest of the first upper electrode lines 510a. The first upper electrode line 510a having a width larger than the width Wt21 of the rest of the first upper electrode lines 510a may be referred to as an extended first upper electrode line, not illustrated. For example, widths of the first upper electrode lines 510a, provided on the via line 410 and covering only a portion of the upper surface of the via line 410, may be increased. Thus, the extended first upper electrode lines 512a may cover the entire upper surface of the via line 410.

Similarly, one or a portion of the second upper electrode lines 510b may be extended. For example, a width of one, or widths of a portion, of the second upper electrode lines 510b disposed on the via line 410 may be selectively increased. For example, widths Wt21 and Wt22 of one or a portion of the second upper electrode lines 510b may be substantially equal to or larger than widths Wt21 of the rest of the second upper electrode lines 510b. The second upper electrode line 510b having a width Wt22 larger than the width Wt21 of the rest of the second upper electrode lines 510b may be referred to as an extended second upper electrode line 512b. For example, widths of the second upper electrode lines 510b, provided on the via line 410 and covering only a portion of the upper surface of the via line 410, may be increased. Thus, the extended second upper electrode lines 512b may cover the entire upper surface of the via line 410.

For example, the width Wt22 of one of the second upper electrode lines 510b disposed on the via line 410 may be larger than the widths Wt21 of the rest of the second upper electrode lines 510b. The width Wt21 of one of the first upper electrode lines 510a disposed on the via line 410 may be substantially equal to the widths Wt21 of the remaining first upper electrode lines 510a.

A spacing of the extended first upper electrode line, not illustrated, may be smaller than spacings of the non-extended first and second upper electrode lines 510a and 510b. Similarly, a spacing Sp22 of the extended second upper electrode line 512b may be smaller than spacings Sp21 of the non-extended first and second upper electrode lines 510a and 510b.

As a result, the pitches Pc22 of the extended first and/or second upper electrode lines 512b, not illustrated, may be substantially equal to the pitches Pc21 of the non-extended first and/or second upper electrode lines 510a and/or 510b.

However, not limited to the first upper electrode line 510a and the second upper electrode line 510b, one or a portion of the first lower electrode line 310a may also selectively extend. This may be applied to one or a portion of the second lower electrode line 310b.

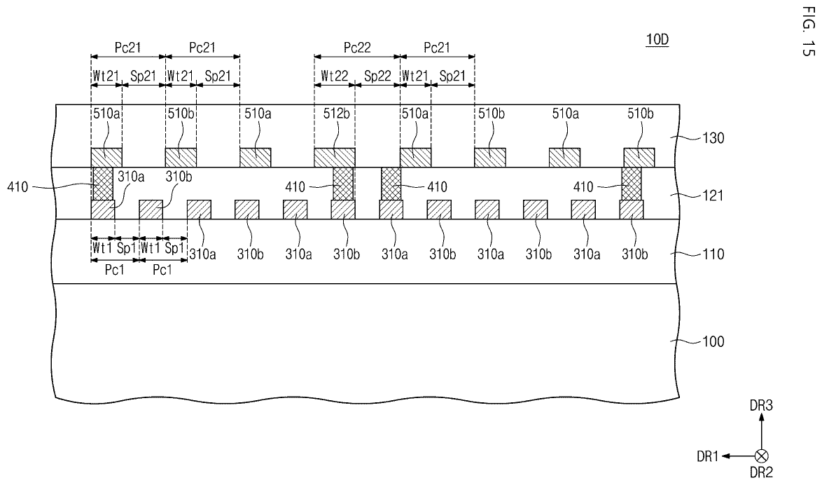

FIG. 15 is a cross-sectional view of a semiconductor device 10D according to an example implementation.

Referring to FIG. 15, in an example implementation, spacings between extended first upper electrode lines, not illustrated, and second upper electrode lines 510b adjacent thereto may be substantially equal to spacings between non-extended first upper electrode lines 510a and the second upper electrode lines 510b.

Similarly, spacings Sp22 between extended second upper electrode lines 512b and first upper electrode lines 510a adjacent thereto may be substantially equal to spacings Sp21 between the non-extended first upper electrode lines 510a and the second upper electrode lines 510b.

As a result, pitches Pc22 of the extended first and/or second upper electrode lines 510b, not illustrated, may be larger than pitches Pc21 of the non-extended first and/or second upper electrode lines 510a and/or 510b.

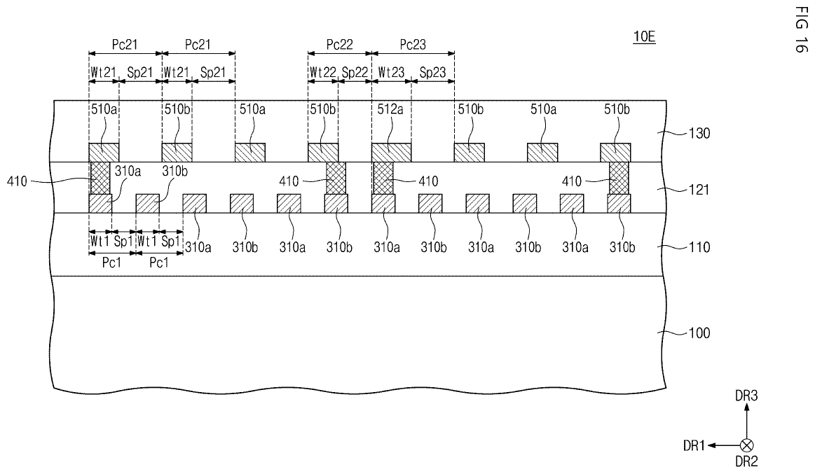

FIG. 16 is a cross-sectional view of a semiconductor device 10E according to an example implementation.

Referring to FIG. 16, in an example implementation, pitches Pc23 of extended first and/or second upper electrode lines 512a, not illustrated, may be increased, while pitches Pc22 of second and/or first upper electrode lines 510b and/or 510a adjacent thereto may be decreased. For example, the pitches Pc23 of the extended first and/or second upper electrode lines 512a, not illustrated, may be increased due to an increase in width, while the pitches Pc22 of the second and/or first upper electrode lines 510b and/or 510a adjacent thereto may be decreased due to a decrease in spacing.

For example, a width Wt23 of the extended first upper electrode line 512a may be larger than widths Wt21 of the non-extended first and second upper electrode lines 510a and 510b, and a spacing Sp23 of the extended first upper electrode line 512a may be substantially equal to spacings Sp21 of the non-extended first and second upper electrode lines 510a and 510b. As a result, the pitch Pc23 of the extended first upper electrode line 512a may be larger than pitches Pc21 of the non-extended first and second upper electrode lines 510a and 510b.

For example, a width Wt22 of the second upper electrode line 510b adjacent to the extended first upper electrode line 512a may be substantially equal to the widths Wt21 of the non-extended first and second upper electrode lines 510a and 510b, and a spacing Sp22 of an adjacent second upper electrode line 510b may be smaller than the spacings Sp21 of the non-extended first and second upper electrode lines 510a and 510b. Accordingly, the pitch Pc22 of the adjacent second upper electrode line 510b may be smaller than the pitches Pc21 of the non-extended first and second upper electrode lines 510a and 510b.

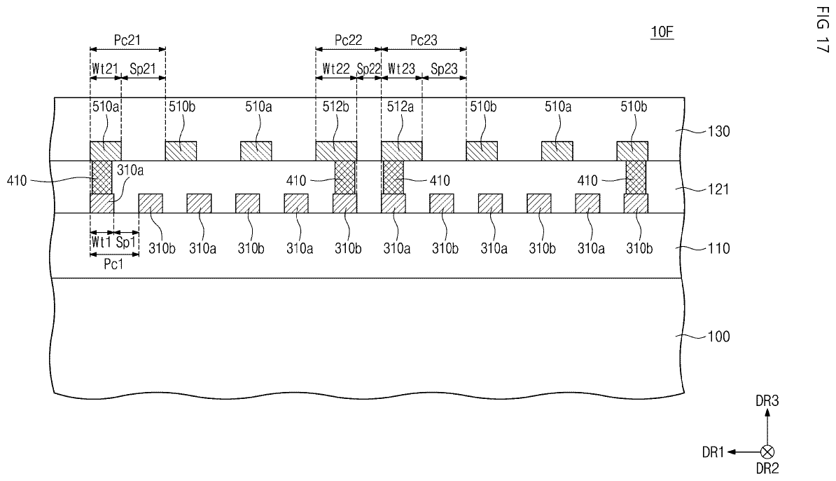

FIG. 17 is a cross-sectional view of a semiconductor device 10F according to an example implementation.

Referring to FIG. 17, in an example implementation, widths of first and second upper electrode lines 512a and 512b covering a portion of an upper surface of a via line 410 may increase. Accordingly, pitches of the extended first and second upper electrode lines 512a and 512b may increase or decrease.

The first upper electrode line 512a and the second upper electrode line 512b, disposed above the via line 410 and adjacent to each other, may be extended. Widths of the first and second upper electrode lines 512a, 512b may increase, but a spacing of the first or second upper electrode line 512a or 512b may decrease. Accordingly, the pitch of the extended first upper electrode line 512a may decrease, while the pitch of the extended second upper electrode line 512b may increase.

In contrast, the pitch of the extended second upper electrode line 512b may decrease, while the pitch of the extended first upper electrode line 512a may increase. For example, when both the second upper electrode line 512b and the first upper electrode line 512a disposed next thereto are extended, a spacing Sp22 between the second upper electrode line 512b and the first upper electrode line 512a may decrease. However, a spacing Sp23 of the first upper electrode line 510a may remain the same. Accordingly, a pitch Pc22 of the second upper electrode line 512b may decrease, while a pitch Pc23 of the first upper electrode line 512a may increase.

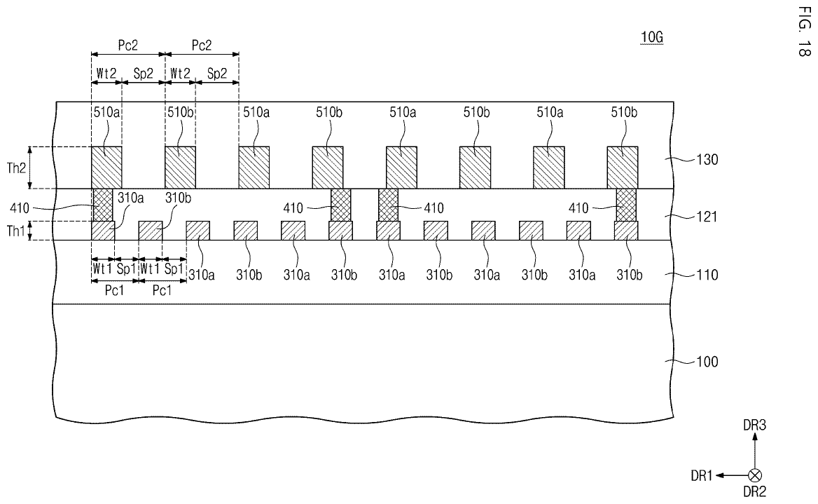

FIG. 18 is a cross-sectional view of a semiconductor device 10G according to an example implementation.

Referring to FIG. 18, in an example implementation, first thicknesses Th1 of first and second lower electrode lines 310a and 310b and second thicknesses Th2 of first and second upper electrode lines 510a and 510b may be different from each other. For example, the first thicknesses Th1 of the first lower electrode lines 310a and the first thicknesses Th1 of the second lower electrode lines 310b may be substantially the same, and the second thicknesses Th2 of the first upper electrode lines 510a and the second thicknesses Th2 of the second upper electrode lines 510b may be substantially the same. However, the second thicknesses Th2 of the first and second upper electrode lines 510a and 510b may be larger than the first thicknesses Th1 of the first and second lower electrode lines 310a and 310b.

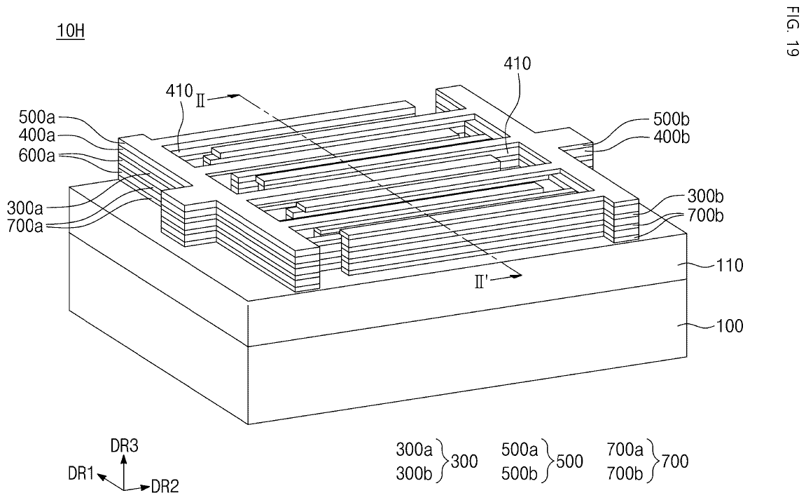

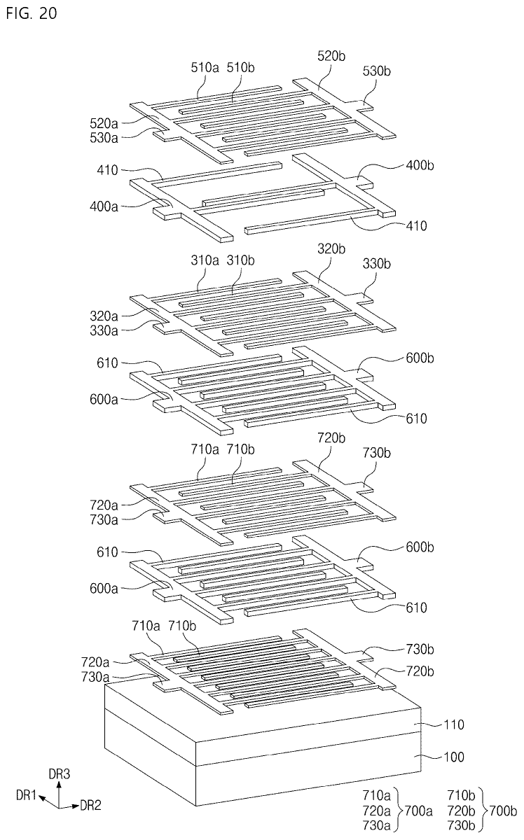

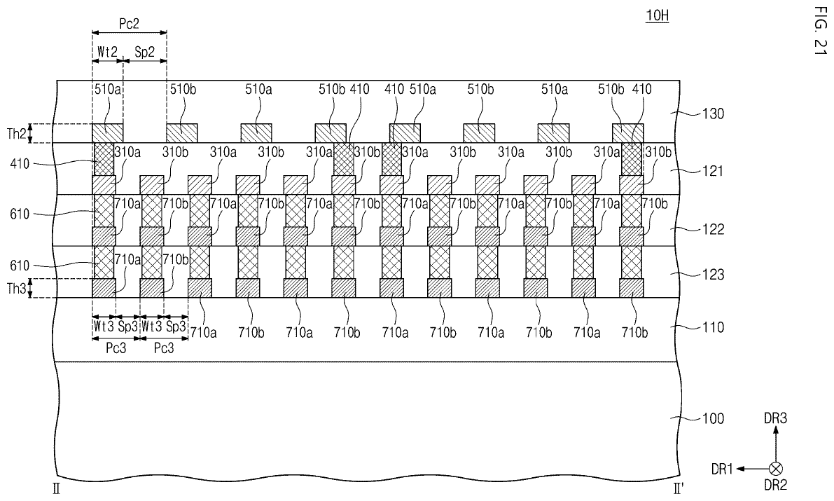

FIG. 19 is a perspective view of a semiconductor device 10H according to an example implementation. FIG. 20 is an exploded perspective view illustrating the semiconductor device 10H of FIG. 19. FIG. 21 is a cross-sectional view taken along line II-II′ of FIG. 19.

Referring to FIGS. 19 to 21, an additional electrode pattern 700 may be provided between a lower electrode pattern 300 and a substrate 100. The additional electrode pattern 700 may be disposed below the lower electrode pattern 300. The additional electrode pattern 700 may be provided on a lower interlayer dielectric 110. For example, the additional electrode pattern 700 may be provided between the lower interlayer dielectric 110 and the lower electrode pattern 300.

The additional electrode pattern 700 may include stacked additional electrode patterns 700. The additional electrode patterns 700 may be stacked between the substrate 100 and the lower electrode pattern 300. For example, two additional electrode patterns 700, vertically stacked on the lower interlayer dielectric 110, may be provided between the lower electrode pattern 300 and the substrate 100.

The additional electrode pattern 700 may include a first additional electrode pattern 700a and a second additional electrode pattern 700b that are separated from each other. The first additional electrode pattern 700a and the second additional electrode pattern 700b may constitute different electrodes. For example, the first additional electrode pattern 700a may be electrically connected to first upper and lower electrode patterns 500a and 300a, and the second additional electrode pattern 700b may be electrically connected to second upper and lower electrode patterns 500b and 300b. Thus, the first upper electrode pattern 500a, the first lower electrode pattern 300a, the first additional electrode pattern 700a, and the via line 410 therebetween may constitute a first electrode. The second upper electrode pattern 500b, the second lower electrode pattern 300b, the second additional electrode pattern 700b, and the via line 410 therebetween may constitute a second electrode.

The additional electrode pattern 700 may include first additional electrode lines 710a and second additional electrode lines 710b that are alternately disposed. For example, the first additional electrode pattern 700a may include the first additional electrode lines 710a. The second additional electrode pattern 700b may include the second additional electrode lines 710b. The first additional electrode lines 710a and the second additional electrode lines 710b may be alternately disposed in one direction, parallel to an upper surface of the substrate 100. However, example implementations are not limited thereto, and the first additional electrode lines 710a and the second additional electrode lines 710b may be alternately disposed in a direction, perpendicular to the one direction parallel to the upper surface of the substrate 100.

The first additional electrode lines 710a and the second additional electrode lines 710b may be elongated. For example, the first additional electrode lines 710a and the second additional electrode lines 710b may be elongated in a direction, perpendicular to a direction in which the first additional electrode lines 710a and the second additional electrode lines 710b are alternately disposed. For example, the first additional electrode lines 710a and the second additional electrode lines 710b may be alternately formed in a first direction DR1 and may be elongated in a second direction DR2, orthogonal to the first direction DR1.

The first additional electrode lines 710a and the second additional electrode lines 710b may be alternately formed. The first additional electrode lines 710a and the second additional electrode lines 710b may be disposed to be spaced apart from each other. For example, the first additional electrode lines 710a and the second additional electrode lines 710b may be spaced apart from each other in the first direction DR1 and/or the second direction DR2. Thus, the first additional electrode lines 710a and the second additional electrode lines 710b may constitute different electrodes.

The first additional electrode lines 710a and the second additional electrode lines 710b may be disposed at a constant pitch. For example, the first additional electrode lines 710a and the second additional electrode lines 710b may be disposed at a third pitch Pc3 in the first direction DR1. The third pitch Pc3 may be substantially equal to the first pitch Pc1 of the first and second lower electrode lines 310a and 310b. For example, the additional electrode pattern 700 may be provided in substantially the same structure as the lower electrode pattern 300. However, example implementations are not limited thereto, and the additional electrode pattern 700 may be provided in a structure, different from the structure of the lower electrode pattern 300. For example, the third pitch Pc3 may be different from the first pitch Pc1.

The third pitch Pc3 may be equal to the sum of a third width Wt3 of the first additional electrode line 710a and a third spacing Sp3 between the first additional electrode line 710a and the second additional electrode line 710b. Alternatively, the third pitch Pc3 may be equal to the sum of a third width Wt3 of the second additional electrode line 710b and the third spacing Sp3 between the first additional electrode line 710a and the second additional electrode line 710b.

The width of the first additional electrode line 710a may be a width of one of the first additional electrode lines 710a. Widths of the first additional electrode lines 710a may be substantially the same. The width of the second additional electrode line 710b may be a width of one of the second additional electrode lines 710b. Widths of the second additional electrode lines 710b may be substantially the same. The width of the first additional electrode line 710a and the width of the second additional electrode line 710b may be substantially the same.

The width of the first additional electrode line 710a or the width of the second additional electrode line 710b may be measured in the first direction DR1. The spacing between the first additional electrode line 710a and the second additional electrode line 710b may be measured in the first direction DR1.

The first additional electrode line 710a and the second additional electrode line 710b may have a third thickness Th3. The third thickness Th3 may be measured in a third direction DR3.

The first additional electrode pattern 700a may include a first additional strap line 720a connecting the first additional electrode lines 710a. The second additional electrode pattern 700b may include a second additional strap line 720b connecting the second additional electrode lines 710b.

The first additional electrode pattern 700a may include a first additional pad portion 730a connected to the first additional strap line 720a.

Thus, the first additional strap line 720a connected to the first additional pad portion 730a and the first additional electrode lines 710a connected to the first additional strap line 720a may constitute a first electrode. For example, the first additional pad portion 730a, the first additional strap line 720a, and the first additional electrode lines 710a may be electrically connected, and the first additional electrode pattern 700a may constitute a first electrode. In an example implementation, the first additional pad portion 730a, the first additional strap line 720a, and the first additional electrode lines 710a may be integrally provided.

The second additional electrode pattern 700b may include a second additional pad portion 730b connected to the second additional strap line 720b. The second additional strap line 720b connected to the second additional pad portion 730b and the second additional electrode lines 710b connected to the second additional strap line 720b may constitute a second electrode. For example, the second additional pad portion 730b, the second additional strap line 720b, and the second additional electrode lines 710b may be electrically connected, and the second additional electrode pattern 700b may constitute a second electrode. In an example implementation, the second additional pad portion 730b, the second additional strap line 720b, and the second additional electrode lines 710b may be integrally provided.

A second interlayer dielectric 122 may be provided between the first interlayer dielectric 121 and the lower interlayer dielectric 110. The second interlayer dielectric 122 may cover one of the additional electrode patterns 700. The second interlayer dielectric 122 may fill a space between the first additional electrode lines 710a and the second additional electrode lines 710b of a single additional electrode pattern 700. Thus, the second interlayer dielectric 122 may be disposed between the first additional electrode lines 710a and the second additional electrode lines 710b.

A third interlayer dielectric 123 may be provided between the second interlayer dielectric 122 and the lower interlayer dielectric 110. The third interlayer dielectric 123 may cover another of the additional electrode patterns 700. In another of the additional electrode patterns 700, the third interlayer dielectric 123 may fill a space between the first additional electrode lines 710a and the second additional electrode lines 710b. Thus, the third interlayer dielectric 123 may be disposed between the first additional electrode lines 710a and the second additional electrode lines 710b.

Accordingly, the first electrode, the second electrode, and the second interlayer dielectric 122 and the third interlayer dielectric 123 provided therebetween may constitute a capacitor. The second interlayer dielectric 122 and the third interlayer dielectric 123 may function as a dielectric.

Although not illustrated, the additional electrode pattern 700 may be provided not only between the lower electrode pattern 300 and the substrate 100 but also over the upper electrode pattern 500. For example, the additional electrode pattern 700 may also be stacked on the upper interlayer dielectric 130. An additional interlayer dielectric may be further provided to cover the additional electrode pattern 700.

The additional electrode pattern 700 may vertically overlap the lower electrode pattern 300. For example, the additional electrode pattern 700 may be provided under the lower electrode pattern 300. At least one of the first additional electrode lines 710a may vertically overlap at least one of the first lower electrode lines 310a.

In an example implementation, a structure of the additional electrode pattern 700 may be substantially the same as the structure of the lower electrode pattern 300. For example, a third pitch Pc3 may be substantially equal to a first pitch Pc1. The first additional electrode lines 710a may vertically overlap the first lower electrode lines 310a, and the second additional electrode lines 710b may vertically overlap the second lower electrode lines 310b.

In an example implementation, the structure of the additional electrode pattern 700 may be different from the structure of the lower electrode pattern 300. For example, the third pitch Pc3 may be different from the first pitch Pc1. One or a portion of the first additional electrode lines 710a may vertically overlap one or a portion of the first lower electrode lines 310a, and the remaining portion of the first additional electrode lines 710a may not overlap the first lower electrode lines 310a. Also, one or a portion of the second additional electrode lines 710b may vertically overlap one or a portion of the first lower electrode lines 310a, and the remaining portion of the second additional electrode lines 710b may not overlap the second lower electrode lines 310b.

An additional via line 610 may be provided between the first lower electrode line 310a and the first additional electrode line 710a that overlap each other. For example, the additional via line 610 may be provided between one of the first lower electrode lines 310a and one of the first additional electrode lines 710a that vertically overlap each other. Additional via lines 610 may be provided between a portion of the first lower electrode lines 310a and a portion of the first additional electrode lines 710a that vertically overlap each other. The additional via line 610 may penetrate through the third interlayer dielectric 123.

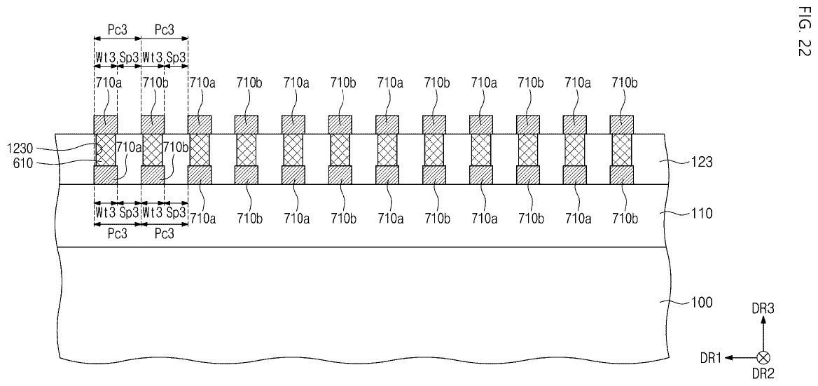

FIGS. 22 to 25 are cross-sectional views, corresponding to line II-II′ of FIG. 19, illustrating a method of manufacturing a semiconductor device 10H according to an example implementation.

Referring to FIG. 22, a lower interlayer dielectric 110 may be formed on a substrate 100. The lower interlayer dielectric 110 may include at least one of a silicon oxide, a silicon nitride, or a silicon oxynitride. First additional electrode lines 710a and the second additional electrode lines 710b may be formed on the lower interlayer dielectric 110.

In another of the additional electrode patterns 700, the first additional electrode lines 710a and the second additional electrode lines 710b may be alternately formed in a first direction DR1. For example, the first additional electrode lines 710a and the second additional electrode lines 710b may be disposed at a third pitch Pc3.

A third interlayer dielectric 123 may be formed on the lower interlayer dielectric 110. The third interlayer dielectric 123 may cover the first additional electrode lines 710a and the second additional electrode lines 710b.

Third grooves 1230 may be formed to penetrate through the third interlayer dielectric 123. The third grooves 1230 may be formed in the third interlayer dielectric 123. The third grooves 1230 may extend in a second direction DR2. The third grooves 1230 may be formed to expose upper surfaces of the first additional electrode lines 710a and/or upper surfaces of the second additional electrode lines 710b.

An additional via conductive layer, not illustrated, may be formed on the third interlayer dielectric 123 to fill the third grooves 1230. The additional via conductive layer, not illustrated, may cover upper surface of the third interlayer dielectric 123.

The additional via conductive layer, not illustrated, may be planarized until the upper surface of the third interlayer dielectric 123 is exposed. The planarization of the additional via conductive layer, not illustrated, may be performed using an etch-back process or a chemical mechanical polishing (CMP) process. As a result, additional via lines 610 may be formed to fill the third grooves 1230. Upper surfaces of the additional via lines 610 may be substantially coplanar with the upper surface of the third interlayer dielectric 123.

The first additional electrode lines 710a and the second additional electrode lines 710b of one of the additional electrode patterns 700 may be formed on the third interlayer dielectric 123. The first additional electrode lines 710a and the second additional electrode lines 710b may be formed on the additional via lines 610. For example, the first additional electrode lines 710a and the second additional electrode lines 710b may be in contact with upper surfaces of the additional via lines 610.

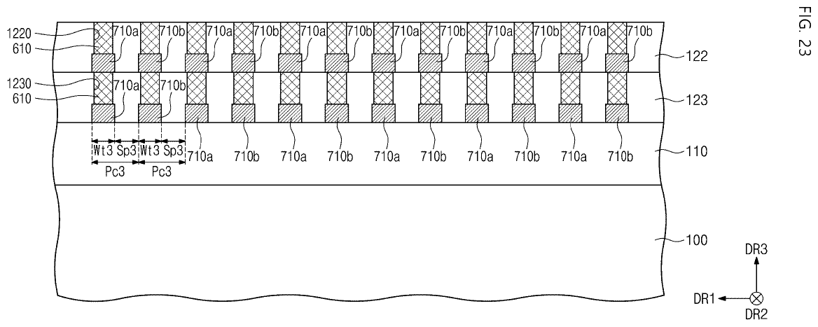

Referring to FIG. 23, a second interlayer dielectric 122 may be formed on the third interlayer dielectric 123. In one of the additional electrode patterns 700, the second interlayer dielectric 122 may cover the first additional electrode lines 710a and the second additional electrode lines 710b. The second interlayer dielectric 122 may include at least one of a silicon oxide, a silicon nitride, or a silicon oxynitride.

Second grooves 1220 may be formed to penetrate through the second interlayer dielectric 122. The second grooves 1220 may be formed in the second interlayer dielectric 122. The second grooves 1220 may extend in the second direction DR2. The second grooves 1220 may be formed to expose upper surfaces of the first additional electrode lines 710a or upper surfaces of the second additional electrode lines 710b.

An additional via conductive layer, not illustrated, may be formed on the second interlayer dielectric 122 to fill the second grooves 1220. The additional via conductive layer, not illustrated, may cover upper surface of the second interlayer dielectric 122.

The additional via conductive layer, not illustrated, may be planarized until the upper surface of the second interlayer dielectric 122 is exposed. The planarization of the additional via conductive layer not illustrated may be performed using an etch-back process or a chemical mechanical polishing (CMP) process. As a result, additional via lines 610 may be formed to fill the second grooves 1220. The upper surfaces of the additional via lines 610 may be substantially coplanar with the upper surface of the second interlayer dielectric 122.

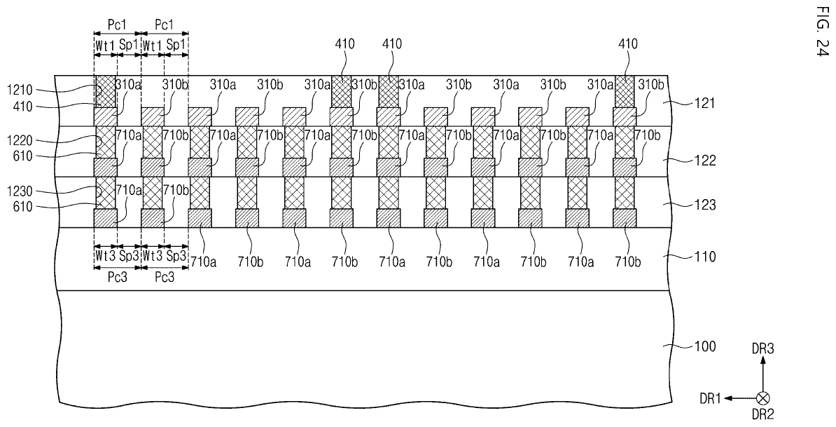

Referring to FIG. 24, first lower electrode lines 310a and second lower electrode lines 310b may be formed on the second interlayer dielectric 122. The first lower electrode lines 310a and the second lower electrode lines 310b may be disposed at a first pitch Pc1. The first lower electrode lines 310a and the second lower electrode lines 310b may be formed on the additional via lines 610. For example, the first lower electrode lines 310a and the second lower electrode lines 310b may be in contact with upper surfaces of the additional via lines 610.

A first interlayer dielectric 121 may be formed on the second interlayer dielectric 122. The first interlayer dielectric 121 may cover the first lower electrode lines 310a and the second lower electrode lines 310b.

At least one first groove 1210 may be formed to penetrate through the first interlayer dielectric 121. The first groove 1210 may be formed in the first interlayer dielectric 121. The first groove 1210 may extend in the second direction DR2. The first groove 1210 may be formed to expose an upper surface of one of the first lower electrode lines 310a or an upper surface of one of the second lower electrode lines 310b. Alternatively, the first grooves 1210 may be formed to expose upper surfaces of a portion of the first lower electrode lines 310a and/or upper surfaces of a portion of the second lower electrode lines 310b. The remaining portion of the first lower electrode lines 310a and the remaining portion of the second lower electrode lines 310b may be covered with the first interlayer dielectric 121.

A via conductive layer, not illustrated, may be formed on the first interlayer dielectric 121 to fill the first grooves 1210. The via conductive layer, not illustrated, may cover upper surface of the first interlayer dielectric 121.

The via conductive layer, not illustrated, may be planarized until the upper surface of the first interlayer dielectric 121 is exposed. The planarization of the via conductive layer not illustrated may be performed using an etch-back process or a chemical mechanical polishing (CMP) process. As a result, at least one via line 410 may be formed to fill at least one first groove 1210. An upper surface of the at least one via line 410 may be substantially coplanar with the upper surface of the first interlayer dielectric 121.

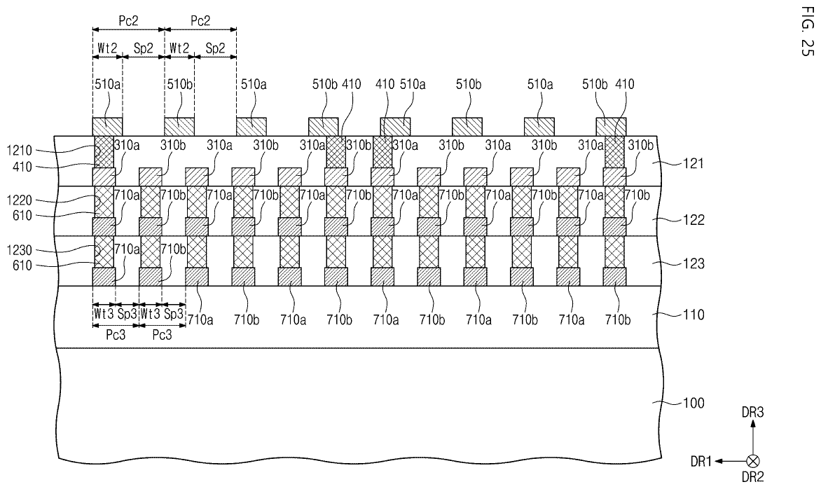

Referring to FIG. 25, first upper electrode lines 510a and second upper electrode lines 510b may be alternately formed on the first interlayer dielectric 121. The first upper electrode lines 510a and the second upper electrode lines 510b may be disposed at a second pitch Pc2 in the first direction DR1.

One or a portion of the first upper electrode lines 510a may be formed on at least one via line 410. For example, the one or a portion of the first upper electrode lines 510a may be in contact with an upper surface of at least one via line 410. The remaining portion of the first upper electrode lines 510a may be formed on the first interlayer dielectric 121. Similarly, one or a portion of the second upper electrode lines 510b may be formed on at least one via line 410. For example, the one or a portion of the second upper electrode lines 510b may be in contact with an upper surface of at least one via line 410. The remaining portion of the second upper electrode lines 510b may be formed on the first interlayer dielectric 121.

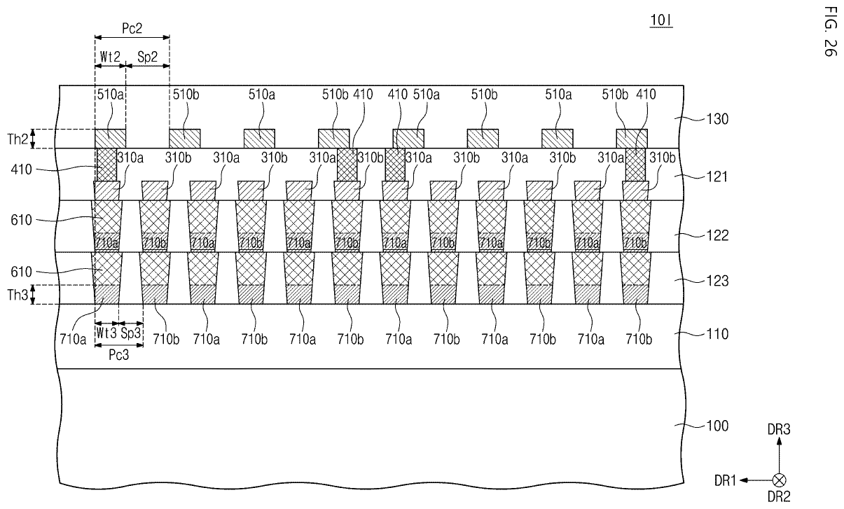

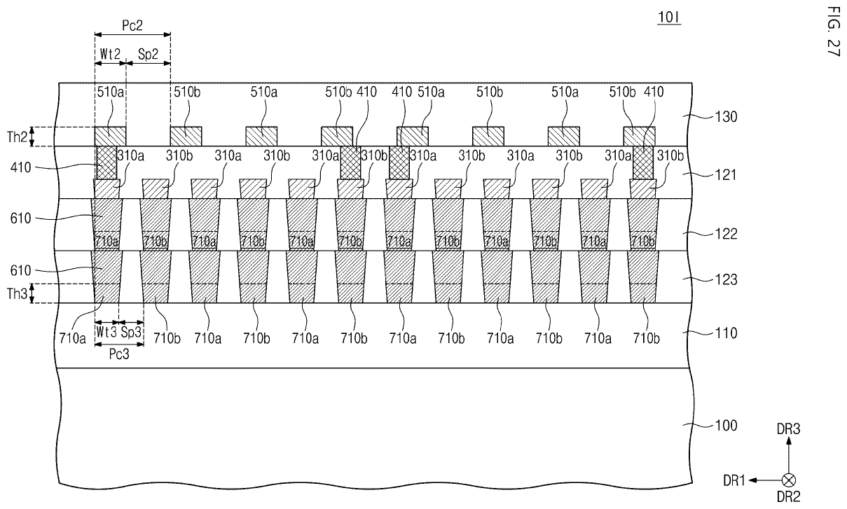

FIG. 26 is a cross-sectional view of a semiconductor device 10I according to an example implementation. FIG. 27 is a cross-sectional view of a semiconductor device 10I according to an example implementation.

Referring to FIG. 26, first additional electrode lines 710a may be provided to be integrated with additional via lines 610. A material of the first additional electrode lines 710a may be substantially the same as a material of the additional via lines 610. Similarly, the second additional electrode lines 710b may be provided to be integrated with the additional via lines 610. In an example implementation, referring to FIG. 27, a material of the second additional electrode lines 710b may be the same as the material of the additional via lines 610.

A width of the integrated portion may increase in an upward direction. For example, widths Wt3 of the first additional electrode lines 710a may increase in an upward direction. Also, widths Wt3 of the second additional electrode lines 710b may increase in an upward direction. Widths of the additional via lines 610 may increase in an upward direction. Widths of lower ends of the additional via lines 610 may be substantially equal to widths of upper ends of the first lower electrode lines 310a. Also, the widths of the lower ends of the additional via lines 610 may be substantially equal to widths of upper ends of the second lower electrode lines 310b.

Side surfaces of the additional via lines 610 may be substantially coplanar with side surfaces of the first lower electrode lines 310a. The side surfaces of the additional via lines 610 may be substantially coplanar with side surfaces of the second lower electrode lines 310b.

In the first additional electrode line 710a having a width increasing in an upward direction, a third pitch Pc3 may be measured with respect to the lower ends of the first and second additional electrode lines 710a and 710b. For example, the third width Wt3 constituting the third pitch Pc3 may be a width of a lower end of the first or second additional electrode line 710a or 710b. Also, a third spacing Sp3 constituting the third pitch Pc3 may be a spacing between the lower portion of the first additional electrode line 710a and the lower end of the second additional electrode line 710b.

An etch-stop layer 112 may be provided on a lower interlayer dielectric 110. The first additional electrode lines 710a and the second additional electrode lines 710b may be provided on the etch-stop layer 112. The etch-stop layer 112 may be provided between the lower interlayer dielectric 110 and a third interlayer dielectric 123. However, example implementations are not limited thereto, and the etch-stop layer 112 may also be provided between a second interlayer dielectric 122 and the third interlayer dielectric 123, as necessary.

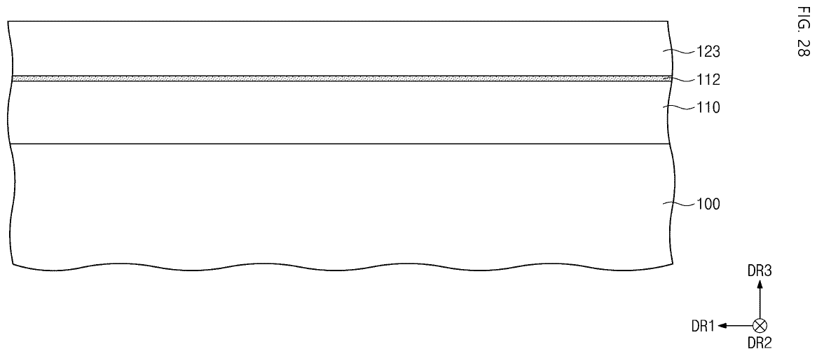

FIGS. 28 to 36 are cross-sectional views illustrating a method of manufacturing a semiconductor device 10I according to an example implementation.

Referring to FIG. 28, a lower interlayer dielectric 110 may be provided on a substrate 100. The lower interlayer dielectric 110 may include at least one of a silicon oxide, a silicon nitride, or a silicon oxynitride.

An etch-stop layer 112 may be provided on the lower interlayer dielectric 110. A material of the etch-stop layer 112 may be different from the material of the lower interlayer dielectric 110. The etch-stop layer 112 may have an etch selectivity with respect to the underlying lower interlayer dielectric 110. For example, the lower interlayer dielectric 110 may be formed of a silicon oxide, and the etch-stop layer 112 may be formed of a silicon nitride and/or a silicon oxynitride.

A third interlayer dielectric 123 may be formed on the etch-stop layer 112. The third interlayer dielectric 123 may cover an upper surface of the etch-stop layer 112. The third interlayer dielectric 123 may include at least one of a silicon oxide, a silicon nitride, or a silicon oxynitride.

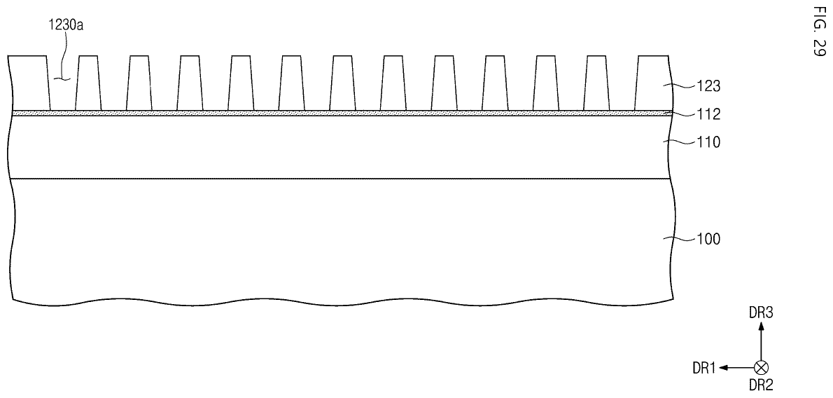

Referring to FIG. 29, third grooves 1230a may be formed to penetrate through the third interlayer dielectric 123. The third grooves 1230a may be formed in the third interlayer dielectric 123. The third grooves 1230a may be formed at positions at which the first and second additional electrode lines 710a and 710b of another of the additional electrode patterns 700 are to be formed. The third grooves 1230a may be recessed until the upper surface of the etch-stop layer 112 is exposed. The third grooves 1230a may extend in a second direction DR2.

Widths of the third grooves 1230a may increase in an upward direction. The widths of the third grooves 1230a may be measured in a first direction DR1.

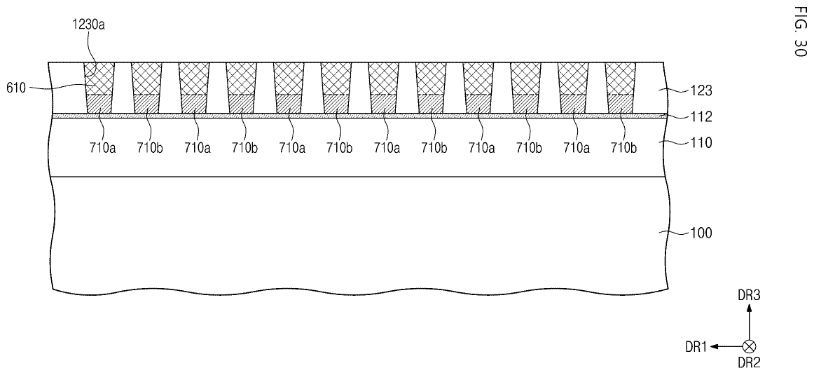

Referring to FIG. 30, the first and second additional electrode lines 710a and 710b of another of the additional electrode patterns 700 and the additional via lines 610 may be formed within the third grooves 1230a. For example, the first and second additional electrode lines 710a and 710b may fill lower portions of the third grooves 1230a. An additional via conductive layer, not illustrated, may be formed on the first and second additional electrode lines 710a and 710b formed within the third grooves 1230a. The additional via conductive layer, not illustrated, may also be formed on the third interlayer dielectric 123. In an example implementation, a material of the first and second additional electrode lines 710a and 710b and a material of the additional via conductive layer, not illustrated, are substantially the same, so that the first and second additional electrode lines 710a and 710b and the additional via conductive layer, not illustrated, may be continuously formed.

Accordingly, the first and second additional electrode lines 710a and 710b and the additional conductive layer, not illustrated, may be continuously formed, so that the manufacturing process of the semiconductor device 10I may be simplified. In addition, the manufacturing cost of the semiconductor device 10I may be reduced.

The additional via conductive layer, not illustrated, may be planarized until the upper surface of the third interlayer dielectric 123 is exposed. The planarization of the additional via conductive layer, not illustrated, may be performed using an etch-back process or a chemical mechanical polishing (CMP) process. As a result, additional via lines 610 may be formed to fill the third grooves 1230a. Upper surfaces of the additional via lines 610 may be substantially coplanar with the upper surface of the third interlayer dielectric 123.

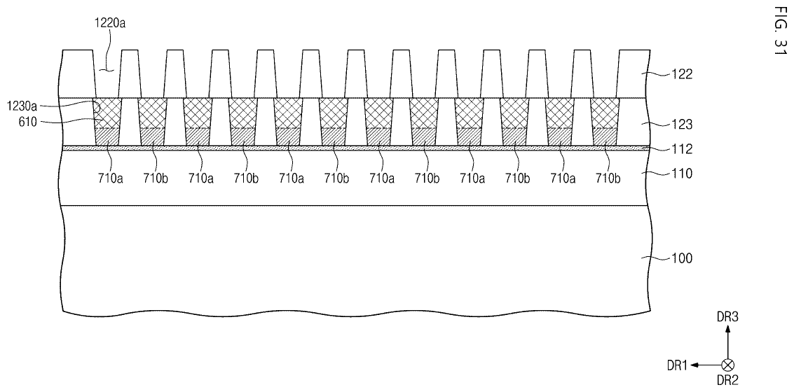

Referring to FIG. 31, a second interlayer dielectric 122 may be formed on the third interlayer dielectric 123. The second interlayer dielectric 122 may cover the upper surface of the third interlayer dielectric 123.

Second grooves 1220a may be formed to penetrate through the second interlayer dielectric 122. The second grooves 1220a may be formed in the second interlayer dielectric 122. The second grooves 1220a may be formed on the additional via lines 610. The second grooves 1220a may be recessed until the upper surfaces of the additional via lines 610 are exposed. The second grooves 1220a may extend in a second direction DR2.

Widths of the second grooves 1220a may increase in an upward direction. The widths of the second grooves 1220a may be measured in the first direction DR1.

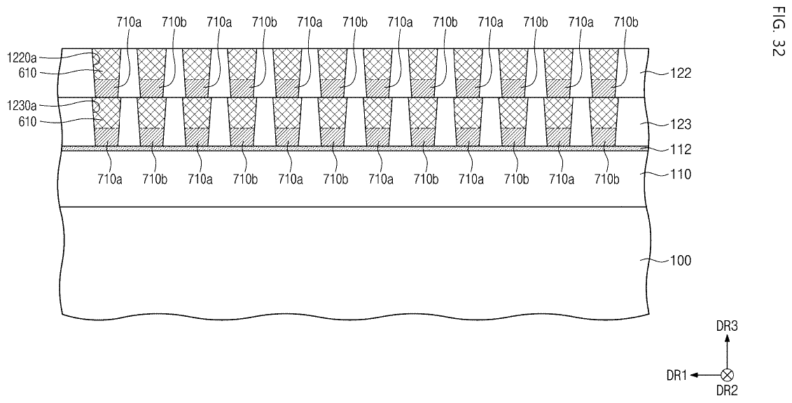

Referring to FIG. 32, the first and second additional electrode lines 710a and 710b of one of the additional electrode patterns 700 and the additional via lines 610 may be formed within the second grooves 1220a. For example, the first and second additional electrode lines 710a and 710b may fill lower portions of the second grooves 1220a. An additional via conductive layer, not illustrated, may be formed on the first and second additional electrode lines 710a and 710b formed within the second grooves 1220a. The additional via conductive layer, not illustrated, may also be formed on the second interlayer dielectric 122. In an example implementation, a material of the first and second additional electrode lines 710a and 710b and a material of the additional via conductive layer, not illustrated, are substantially the same, so that the first and second additional electrode lines 710a and 710b and the additional via conductive layer, not illustrated, may be continuously formed.

The additional via conductive layer, not illustrated, may be planarized until an upper surface of the second interlayer dielectric 122 is exposed. The planarization of the additional via conductive layer not illustrated may be performed using an etch-back process or a chemical mechanical polishing (CMP) process. As a result, additional via lines 610 may be formed to fill the second grooves 1220a. Upper surfaces of the additional via lines 610 may be substantially coplanar with the upper surface of the second interlayer dielectric 122.

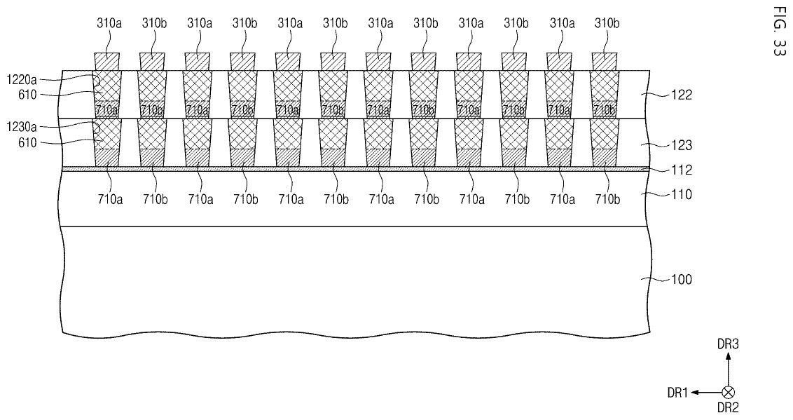

Referring to FIG. 33, first lower electrode lines 310a and second lower electrode lines 310b may be formed on the second interlayer dielectric 122. For example, the first lower electrode lines 310a and the second lower electrode lines 310b may be formed on the additional via lines 610 within the second interlayer dielectric 122. The first lower electrode lines 310a and the second lower electrode lines 310b may be disposed at a first pitch Pc1 in the first direction DR1.

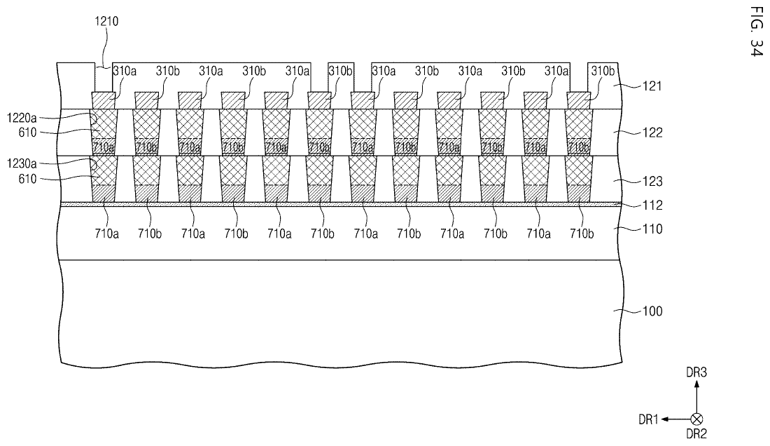

Referring to FIG. 34, a first interlayer dielectric 121 may be formed on the second interlayer dielectric 122. The first interlayer dielectric 121 may cover the first lower electrode lines 310a and the second lower electrode lines 310b.

At least one first groove 1210 may be formed to penetrate through the first interlayer dielectric 121. The first groove 1210 may be formed in the first interlayer dielectric 121. The first groove 1210 may extend in the second direction DR2. The first groove 1210 may expose an upper surface of one of the first lower electrode lines 310a or an upper surface of one of the second lower electrode lines 310b. Alternatively, the first grooves 1210 may expose upper surfaces of a portion of the first lower electrode lines 310a and/or upper surfaces of a portion of the second lower electrode lines 310b. The remaining portion of th first lower electrode lines 310a, and the remaining portion of the second lower electrode lines 310b may be covered with the first interlayer dielectric 121.

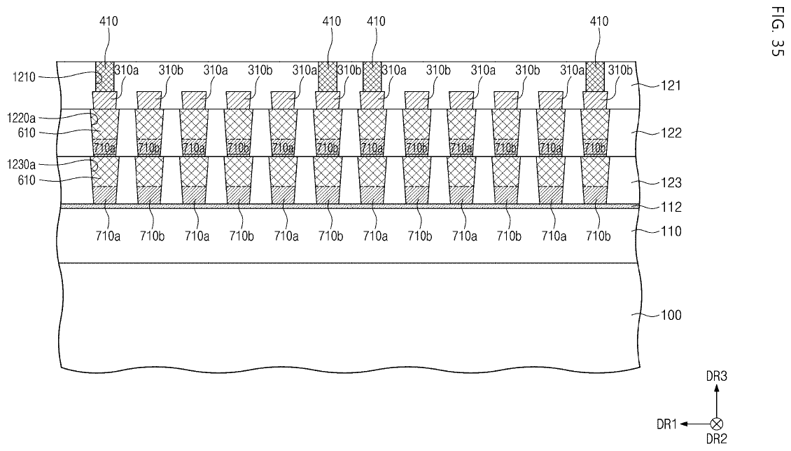

Referring to FIG. 35, a via conductive layer, not illustrated, may be formed on the first interlayer dielectric 121 to fill at least one first groove 1210. The via conductive layer, not illustrated, may cover an upper surface of the first interlayer dielectric 121.

The via conductive layer, not illustrated, may be planarized until the upper surface of the first interlayer dielectric 121 is exposed. The planarization of the via conductive layer, not illustrated, may be performed using an etch-back process or a chemical mechanical polishing (CMP) process. As a result, at least one via line 410 may be formed to fill at least one first groove 1210. An upper surface of the at least one via line 410 may be substantially coplanar with the upper surface of the first interlayer dielectric 121.

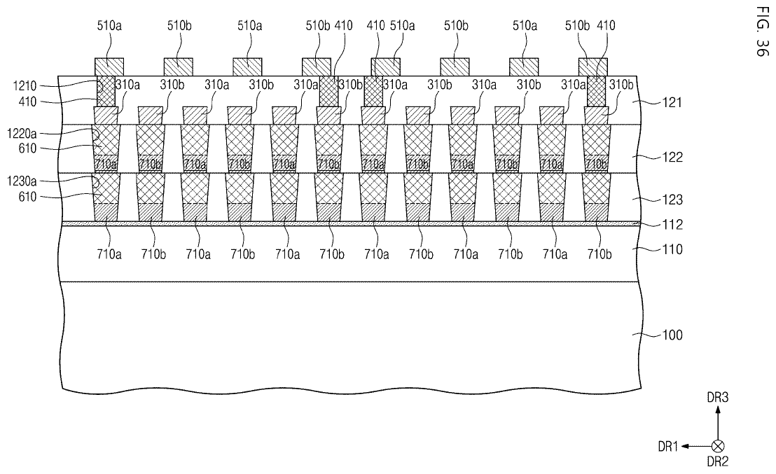

Referring to FIG. 36, first upper electrode lines 510a and second upper electrode lines 510b may be formed on the first interlayer dielectric 121. The first upper electrode lines 510a and the second upper electrode lines 510b may be alternately formed in the first direction DR1. The first upper electrode lines 510a and the second upper electrode lines 510b may be disposed at a second pitch Pc2.

One or a portion of the first upper electrode lines 510a may be formed on at least one via line 410. For example, the one or a portion of the first upper electrode lines 510a may be in contact with the upper surface of at least one via line 410. The remaining portion of the first upper electrode lines 510a may be formed on the first interlayer dielectric 121. Similarly, one or a portion of the second upper electrode lines 510b may be formed on at least one via line 410. For example, the one or a portion of the second upper electrode lines 510b may be in contact with the upper surface of at least one via line 410. The remaining portion of the second upper electrode lines 510b may be formed on the first interlayer dielectric 121.

FIG. 37 is a cross-sectional view of a semiconductor device 10J according to an example implementation.

Referring to FIG. 37, the semiconductor device 10J may have a chip-to-chip (C2C) structure. The C2C structure may refer to connecting at least one upper chip, including a cell region CEL, and a lower chip, including a peripheral circuit region PERI, through bonding. In an example implementation, the bonding may refer to electrically or physically connecting a bonding metal, formed on an uppermost metal layer of the upper chip, and a bonding metal, formed on an uppermost metal layer of the lower chip. For example, when the bonding metals are formed of copper (Cu), the bonding may be Cu-Cu bonding. For example, the bonding metals may include aluminum (Al) or tungsten (W).

The peripheral circuit region PERI and the cell region CEL of the semiconductor device 10J may each include a peripheral pad bonding region PA, a wordline bonding region WLBA, and a bitline bonding region BLBA.

The peripheral circuit region PERI may include a first substrate 100 and a plurality of peripheral transistors 111 formed on the first substrate 100. A lower interlayer dielectric 110 including one or more interlayer layers may be provided on the plurality of peripheral transistors 111, and a plurality of interconnections 113 may be provided in the lower interlayer dielectric 110 to connect the plurality of peripheral transistors 111. The plurality of peripheral transistors 111 may be combined with the wires 113 to constitute various core circuits.

The lower interlayer dielectric 110 may be disposed on the first substrate 100 and may include an insulating material such as a silicon oxide or a silicon nitride.

A first interlayer dielectric 121 may be provided on the lower interlayer dielectric 110. An upper interlayer dielectric 130 may be provided on the first interlayer dielectric 121.

The peripheral circuit region PERI may include a capacitor structure CAP. The capacitor structure CAP may be provided on the lower interlayer dielectric 110. The capacitor structure CAP may be provided in the first interlayer dielectric 121 and the upper interlayer dielectric 130. The capacitor structure CAP may include first and second lower electrode lines 310a and 310b, first and second upper electrode lines 510a and 510b, and at least one via line 410 provided therebetween. In an example implementation, the capacitor structure CAP may be included in a charge pump circuit.

The cell region CEL may include at least one memory cell structure. The cell region CEL may include a second substrate 810 and a common source line 820.

A plurality of wordlines 830 (831 to 838) may be stacked on the second substrate 810 in a direction, perpendicular to an upper surface of the second substrate 810. String select lines and a ground select line may be disposed on upper and lower portions of wordlines 830, and a plurality of wordlines 830 may be disposed between the string select lines and the ground select line.

The second substrate 810 may be a silicon substrate, a silicon-germanium substrate, a germanium substrate, or a substrate having a monocrystalline epitaxial layer grown on a monocrystalline silicon substrate. A plurality of channel structures CH may be formed in the cell region CEL.

The channel structure CH may be provided in the bitline bonding region BLBA and may extend in a direction, perpendicular to an upper surface of the second substrate 810, to penetrate through the wordlines 830, the string select lines, and the ground select line. The channel structure CH may include a data storage layer, a channel layer, a buried insulating layer, or the like. The channel layer may be electrically connected to a first metal interconnection 850c and a second metal interconnection 860c in the bitline bonding region BLBA. For example, the second metal interconnection 860c may be a bitline and may be connected to the channel structure CH through the first metal interconnection 850c. The bitline may extend in a second direction DR2, parallel to an upper surface of the second substrate 810.

In the bitline bonding region BLBA, a first bonding pattern 752 may be formed on an uppermost metal layer of the peripheral circuit region PERI, and a second bonding pattern 892 having the same shape as the first bonding pattern 752 may be formed on an uppermost metal layer of the cell region CEL. The first bonding pattern 752 of the peripheral circuit region PERI and the second bonding pattern 892 of the cell region CEL may be electrically connected to each other through bonding. In the bitline bonding region BLBA, the bitline may be electrically connected to a page buffer included in the peripheral circuit region PERI. For example, a portion of the peripheral transistors 111 of the peripheral circuit region PERI may provide a page buffer, and the bitline may be electrically connected to the peripheral transistors 111 providing the page buffer through a first bonding metal 772c of the peripheral circuit region PERI and a second bonding metal 872c of the cell region CEL.

In the wordline bonding area WLBA, the wordlines 830 of the cell region CEL may extend in a first direction DR1, parallel to the upper surface of the second substrate 810, and may be connected to a plurality of cell contact plugs 840 (841 to 847). A first metal interconnection 850b and a second metal interconnection 860b may be sequentially connected to the upper portions of the cell contact plugs 840 connected to the wordlines 830. The cell contact plugs 840 may be connected to the peripheral circuit region PERI through the first bonding metal 772b of the peripheral circuit region PERI and the second bonding metal 872b of the cell region CEL, in the wordline bonding region WLBA.

The cell contact plugs 840 may be electrically connected to a row decoder included in the peripheral circuit region PERI. For example, a portion of the peripheral transistors 111 of the peripheral circuit region PERI may provide a row decoder, and the cell contact plugs 840 may be electrically connected to the peripheral transistors 111 providing the row decoder through the first bonding metal 772b of the peripheral circuit region PERI and the second bonding metal 872b of the cell region CEL.

In the wordline bonding area WLBA, a first bonding metal 772b may be formed in the peripheral circuit region PERI, and a second bonding metal 872c may be formed in the cell region CEL. The first bonding metal 772b and the second bonding metal 872b may be electrically connected to each other through bonding. The first bonding metal 772b and the second bonding metal 872b may be formed of aluminum, copper, or tungsten.

In an external pad bonding region PA, a first bonding metal 772a may be formed at an upper portion of the peripheral circuit region PERI, and a second bonding metal 872a may be formed at an upper portion of the cell region CEL. The first bonding metal 772a and the second bonding metal 872a may be connected through bonding.

A common source line contact plug 880 may be disposed in the external pad bonding region PA. The common source line contact plugs 880 may be formed of a conductive material such as metal, metal compound, or doped polysilicon. The common source line contact plug 880 of the cell region CEL may be electrically connected to the common source line 820. A first metal interconnection 850a and a second metal interconnection 860a may be sequentially stacked on the common source line contact plug 880.

An upper interlayer layer 801 may be formed above the second substrate 810 to cover a surface of the second substrate 810. At least one input/output pad 805 may be disposed in the external pad bonding region PA. At least one input/output pad 805 may be disposed on the upper interlayer layer 801. The input/output pad 805 on the upper interlayer layer 801 may be connected to at least one of the plurality of peripheral transistors 111 disposed in the peripheral circuit region PERI through an input/output contact plug 803.

As set forth above, according to example implementations, at least one via line may be provided between lower electrode lines disposed at a first pitch and upper electrode lines disposed at a second pitch, different from the first pitch, to increase the capacity of a capacitor.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
first lower electrode lines and second lower electrode lines on a substrate and disposed in an alternating fashion in a first direction that is parallel to an upper surface of the substrate;
a first interlayer dielectric covering the first lower electrode lines and the second lower electrode lines;
first upper electrode lines and second upper electrode lines on the first interlayer dielectric and disposed in an alternating fashion in the first direction, at least one of the first upper electrode lines overlapping in a vertical direction with a first lower electrode line of the first lower electrode lines, and at least another of the first upper electrode lines overlapping in the vertical direction with a second lower electrode line of the second lower electrode lines; and
a via line between the at least one of the first upper electrode lines and the first lower electrode line that are overlapped in the vertical direction, the via line extending through the first interlayer dielectric,
wherein the first upper electrode lines and the first lower electrode lines are electrically connected to one another, and
wherein the second upper electrode lines and the second lower electrode lines are electrically connected to one another.

2. The semiconductor device of claim 1, wherein
the first lower electrode lines and the second lower electrode lines are disposed in the first direction at a first pitch, and
the first upper electrode lines and the second upper electrode lines are disposed in the first direction at a second pitch different from the first pitch.

3. The semiconductor device of claim 2, wherein
the first pitch is equal to a sum of a first width of a lower electrode line of the first or second lower electrode lines and a first spacing between a first lower electrode line of the first lower electrode lines and an adjacent second lower electrode line of the second lower electrode lines,
the second pitch is equal to a sum of a second width of an upper electrode line of the first or second upper electrode lines and a second spacing between a first upper electrode line of the first upper electrode lines and an adjacent second upper electrode line of the second upper electrode lines, and
the second width is larger than the first width.

4. The semiconductor device of claim 3, wherein
the second spacing is larger than the first spacing.

5. The semiconductor device of claim 1, comprising:
a first lower strap line connecting the first lower electrode lines;
a first upper strap line connecting the first upper electrode lines;
a second lower strap line connecting the second lower electrode lines; and
a second upper strap line connecting the second upper electrode lines,
wherein the first lower electrode lines and the second lower electrode lines are between the first lower strap line and the second lower strap line, and
wherein the first upper electrode lines and the second upper electrode lines are between the first upper strap line and the second upper strap line.

6. The semiconductor device of claim 1, wherein
at least one of the first upper electrode lines has a width that is substantially equal to or larger than a width of remaining first upper electrode lines of the first upper electrode lines.

7. The semiconductor device of claim 1, wherein
at least one of the first lower electrode lines has a width that is substantially equal to or larger than a width of remaining first lower electrode lines of the first lower electrode lines.

8. The semiconductor device of claim 6, wherein
the first upper electrode lines and the second upper electrode lines are disposed at a same pitch in the first direction.

9. The semiconductor device of claim 6, wherein
at least one of the first upper electrode lines comprises an extended first upper electrode line having a width larger than the width of the remaining first upper electrode lines, and
a sum of the width of the extended first upper electrode line and a spacing between the extended first upper electrode line and a second upper electrode line of the second upper electrode lines that is adjacent to the extended first upper electrode line is larger than a sum of a width of the at least another of the first upper electrode lines and a spacing between the at least another of the first upper electrode lines and a second upper electrode line of the second upper electrode lines that is adjacent to the at least another of the first upper electrode lines.

10. The semiconductor device of claim 1, wherein
a portion of the second upper electrode lines overlaps a portion of the second lower electrode lines, and
the via line is between the portion of the second upper electrode lines and the portion of the second lower electrode lines.

11. The semiconductor device of claim 1, wherein
a material of the first upper electrode lines is different from a material of the first lower electrode lines.

12. The semiconductor device of claim 6, wherein
thicknesses of the first upper electrode lines are larger than thicknesses of the first lower electrode lines.

13. The semiconductor device of claim 1, comprising:
first additional electrode lines between the substrate and the first lower electrode lines, the first additional electrode lines electrically connected to the first lower electrode lines; and
second additional electrode lines between the substrate and the second lower electrode lines, the second additional electrode lines electrically connected to the second lower electrode lines,
wherein the first additional electrode lines and the second additional electrode lines are alternately disposed in the first direction.

14. The semiconductor device of claim 1, wherein
the first upper electrode lines, the first lower electrode lines, and the via line that are electrically connected constitute a first electrode,
the second upper electrode lines and the second lower electrode lines that are electrically connected constitute a second electrode, and
the first electrode, the second electrode, and the first interlayer dielectric between the first electrode and the second electrode constitute a capacitor.

15. A semiconductor device comprising:
first lower electrode lines and second lower electrode lines on a substrate and disposed alternately in a first direction that is parallel to an upper surface of the substrate, the first lower electrode lines and the second lower electrode lines being disposed at a first pitch in the first direction;
a first interlayer dielectric covering the first lower electrode lines and the second lower electrode lines;
first upper electrode lines and second upper electrode lines on the first interlayer dielectric and disposed in an alternating fashion in the first direction, the first upper electrode lines and the second upper electrode lines being disposed at a second pitch larger than the first pitch in the first direction, and at least one of the first upper electrode lines overlapping in a vertical direction with a first lower electrode line of the first lower electrode lines; and
at least one via line between the at least one of the first upper electrode lines and the first lower electrode line of the first lower electrode lines that in a vertical direction overlaps one another, the at least one via line extending through the first interlayer dielectric,
wherein the first upper electrode lines and the first lower electrode lines are electrically connected to one another, and
wherein the second upper electrode lines and the second lower electrode lines are electrically connected to one another.

16. The semiconductor device of claim 15, wherein
at least one of the first upper electrode lines has a width that is substantially equal to or larger than a width of remaining first upper electrode lines of the first upper electrode lines.

17. The semiconductor device of claim 16, wherein
at least another of the first upper electrode lines in the vertical direction overlaps with a second lower electrode line of the second lower electrode lines.

18. The semiconductor device of claim 15, wherein
the first lower electrode lines and the at least one via line comprise a same material, and
the first lower electrode line of the first lower electrode lines and the at least one via line are integrally provided.

19. The semiconductor device of claim 15, comprising:
first additional electrode lines between the substrate and the first lower electrode lines, the first additional electrode lines electrically connected to the first lower electrode lines; and
second additional electrode lines between the substrate and the second lower electrode lines, the second additional electrode lines electrically connected to the second lower electrode lines,
wherein the first additional electrode lines and the second additional electrode lines are alternately disposed in the first direction.

20. The semiconductor device of claim 15, wherein
the first upper electrode lines, the first lower electrode lines, and the at least one via line that are electrically connected constitute a first electrode,
the second upper electrode lines and the second lower electrode lines that are electrically connected constitute a second electrode, and
the first electrode, the second electrode, and the first interlayer dielectric between the first electrode and the second electrode constitute a capacitor.
